(19) United States
(12) Patent Application Publication
(10) Pub. No.: US 2026/0343969 A1
(43) Pub. Date: Oct. 29, 2026

(54) SEMICONDUCTOR DEVICE

(71) Applicant: FUJI ELECTRIC CO., LTD., Kanagawa (JP)

(72) Inventor: Tohru SHIRAKAWA, Matsumoto-city (JP)

(21) Appl. No.: 19/714,651

(22) Filed: Jun. 22, 2026

Related U.S. Application Data
(63) Continuation of application No. PCT/JP2025/025381, filed on Jul. 15, 2025.

(30) Foreign Application Priority Data
Jul. 16, 2024 (JP) 2024-113405

(51) Int. Cl. H10D 62/10; H10D 8/00; H10D 12/00; H10D 62/60; H10D 64/27; H10D 84/00

(52) U.S. Cl. CPC H10D 62/126; H10D 8/422; H10D 12/415; H10D 12/481; H10D 62/60; H10D 64/519; H10D 84/161

(57) ABSTRACT

A semiconductor device is provided including a semiconductor substrate having an upper surface and a lower surface, a plurality of trench portions extending in a first direction on the upper surface, a first active gate runner extending in a second direction intersecting the first direction above the upper surface, and a second active gate runner extending in the second direction and provided apart from the first active gate runner in the second direction, in which a spaced region is provided between the first active gate runner and the second active gate runner along the second direction, the plurality of trench portions have a first gate trench portion, and the first gate trench portion includes a first extending portion extending in the first direction to the spaced region and a first connection portion provided in the spaced region and connecting the first extending portion to the first active gate runner.

### BACKGROUND

### 1. Technical Filed

The present invention relates to a semiconductor device.

### 2. Related Art

Conventionally, the configuration in which a gate runner layer made of metal and a gate electrode are electrically connected without interposing polysilicon therebetween is known (see, for example, Patent Document 1). Also, a semiconductor device including an emitter bridge portion that connects a first region and a second region of the emitter electrode is known (see, for example, Patent Document 2).

### Related Art Documents

### Patent Documents

Patent Document 1: Japanese patent application publication No. 2017-103400

Patent Document 2: Japanese patent application publication No. 2019-68036

### BRIEF DESCRIPTION OF THE DRAWINGS

FIG. 1 illustrates a top view showing one example of the semiconductor device 100 according to one embodiment of the present invention.

FIG. 2A is an enlarged view of region A in FIG. 1.

FIG. 2B is a diagram illustrating the spaced region 180.

FIG. 2C is a diagram illustrating the example of the arrangement of contact hole 54 in the region A.

FIG. 2D is a diagram illustrating another example of the trench portion in the region A.

FIG. 2E is a diagram illustrating another example of the trench portion in the region A.

FIG. 3A is a diagram illustrating the region A of semiconductor device 200 in the comparative example.

FIG. 3B is a diagram illustrating the cross section B-B' of the semiconductor device 200 shown in FIG. 3A.

FIG. 4 is an enlarged top view of the region close to the first active gate runner 131-1 in FIG. 2A.

FIG. 5 is a diagram illustrating the cross section C-C' in FIG. 4.

FIG. 6 is a diagram illustrating the inactive region formed in the manufacturing process of the semiconductor device 200 of the comparative example.

FIG. 7 is an enlarged top view of the region close to the second active gate runner 131-2 in FIG. 2A.

FIG. 8A is the top view of the region A in a modified example of the semiconductor device 100.

FIG. 8B is a diagram illustrating length c.

FIG. 8C is a diagram illustrating another example of the trench portion in the example of FIG. 8A.

FIG. 8D is a diagram illustrating another example of the trench portion in the example of FIG. 8A.

FIG. 9A is a top view of the region A in a modified example of the semiconductor device 100.

FIG. 9B is a diagram illustrating another example of the trench portion in the example of FIG. 9A.

FIG. 9C is a diagram illustrating another example of the trench portion in the example of FIG. 9A.

FIG. 10A is the top view of the region A in a modified example of the semiconductor device 100.

FIG. 10B is a diagram illustrating the example of the arrangement of the contact hole 54 in the example of FIG. 10A.

FIG. 10C is a diagram illustrating another example of the trench portion in the example of FIG. 10A.

FIG. 10D is a diagram illustrating another example of the trench portion in the example of FIG. 10A.

FIG. 11 is an overall top view of the modified example of the semiconductor device 100.

FIG. 12A is an enlarged view of the region A in FIG. 11.

FIG. 12B is a diagram illustrating the example of the arrangement of the contact hole 54 in the example of FIG. 11A.

FIG. 12C is a diagram illustrating another example of the trench portion in the example of FIG. 12A.

FIG. 13 is a diagram illustrating an example of the cross section D-D' in FIG. 12A.

FIG. 14 is a top view of the entire semiconductor device 100 in a modified example.

FIG. 15A is an enlarged view of the region A in FIG. 14.

FIG. 15B is a diagram illustrating the example of the arrangement of the contact hole 54 in the example of FIG. 15A.

FIG. 15C is a diagram illustrating another example of the trench portion in the example of FIG. 15A.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a -Z axis direction are directions opposite to each other. When the Z axis direction is described without describing the signs, it means that the direction is parallel to the + Z axis and the -Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

A region from the center in the depth direction of the semiconductor substrate to the upper surface of the semiconductor substrate may be referred to as an upper surface side. Similarly, a region from the center in the depth direction of the semiconductor substrate to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%. Also, when terms such as “parallel” or “perpendicular” are used, errors within, for example, 5° may be included.

In the present specification, the conductivity type of a doping region doped with an impurity is described as p type or N type. In the present specification, an impurity may specifically mean either an N type donor or a p type acceptor, and may be described as a dopant. In the present specification, doping means introducing a donor or an acceptor into a semiconductor substrate to form the semiconductor exhibiting an N type conductivity type or the semiconductor exhibiting a p type conductivity type.

In the present specification, doping concentration means the concentration of a donor or the concentration of an acceptor in a thermal equilibrium state. In the present specification, net doping concentration means the net concentration obtained by adding a donor concentration as the positive ion concentration and an acceptor concentration as the negative ion concentration, including the polarity of the charges. As an example, when the donor concentration is N_{D} and the acceptor concentration is N_{A}, the net doping concentration at any position is given as N_{D} - N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons.

In this specification, the semiconductor substrate has the N type bulk donors distributed throughout. The bulk donor is a donor due to a dopant substantially uniformly contained in an ingot during manufacture of the ingot serving as a source of the semiconductor substrate. The bulk donor in this example is an element other than hydrogen. The dopant of the bulk donor is, for example, phosphorous, antimony, arsenic, selenium, or sulfur, but is not limited thereto. The bulk donor in this example is phosphorous. Bulk donors are also included in the p type region. The semiconductor substrate may be the wafer cut out from a semiconductor ingot, or may be the chip obtained by singulating the wafer. The semiconductor ingot may be manufactured by any of the Czochralski method (CZ method), the magnetic field applied Czochralski method (MCZ method), or the float zone method (FZ method). The ingot in this example is manufactured by the MCZ method. The bulk donor concentration may use the chemical concentration of bulk donors distributed throughout the semiconductor substrate, and may be a value between 90% and 100% of the chemical concentration. Also, the semiconductor substrate may be the undoped substrate that does not contain a dopant such as phosphorous. In that case, the bulk donor concentration (D0) of the undoped substrate is, for example, 1 × 10¹⁰/cm³ or more and 5 × 10¹²/cm³ or less. The bulk donor concentration (D0) of the undoped substrate is preferably 1 × 10¹¹/cm³ or more. The bulk donor concentration (D0) of the undoped substrate is preferably 5 × 10¹²/cm³ or less. Note that each concentration in the present invention may be a value at room temperature. The value at room temperature may use, as an example, the value at 300 K (Kelvin) (about 26.9° C).

In the present specification, a description of a p+ type or an n+ type means a higher doping concentration than that of the p type or the N type, and a description of a p- type or an n- type means a lower doping concentration than that of the p type or the n type. Also, in this specification, when p++ type or n++ type is described, it means that the doping concentration is higher than that of p+ type or n+ type. The unit system in this specification is the SI unit system unless otherwise specified. Although the unit of length may be expressed in cm, various calculations may be performed after conversion to meters (m).

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In this specification, the doping concentration of an N type region may be referred to as the donor concentration, and the doping concentration of a p type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In this specification, atoms/cm³ or /cm³ is used as the concentration expression per unit volume. This unit is used for the donor concentration or the acceptor concentration in a semiconductor substrate, or for the chemical concentration. The atoms notation may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. The semiconductor substrate may be silicon, may be silicon carbide, may be gallium nitride, may be diamond, or may be gallium oxide.

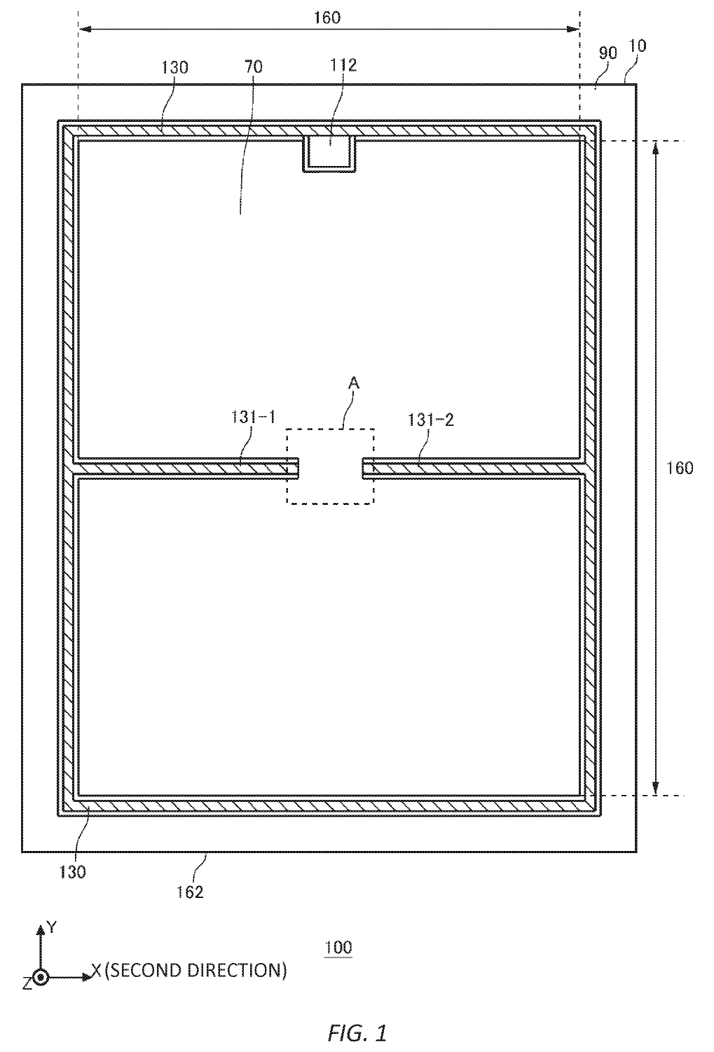

FIG. 1 illustrates a top view showing one example of the semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in the top view. When merely referred to as the top view in the present specification, it means that the semiconductor substrate 10 is viewed from an upper surface side. The semiconductor substrate 10 of this example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1. The active portion 160 may refer to a region overlapping the emitter electrode in top view. Also, a region sandwiched by the active portion 160 in top view may be included in the active portion 160.

The active portion 160 is provided with the transistor portion 70 including the transistor element such as an IGBT (Insulated Gate Bipolar Transistor). However, the transistor portion 70 may be provided with the MOSFET (Metal-Oxide-Semiconductor Field-Effect-Transistor). The active portion 160 may further be provided with the diode portion including the diode element such as the freewheeling diode (FWD).

The transistor portion 70 has the p type collector region in a region in contact with the lower surface of the semiconductor substrate 10. Also, the transistor portion 70 has, on the upper surface side of the semiconductor substrate 10, gate structures periodically arranged and each having an n type emitter region, a p type base region, a gate conductive portion, and a gate dielectric film.

The semiconductor device 100 may have one or more pads above the semiconductor substrate 10. The semiconductor device 100 of this example has a gate pad 112. The semiconductor device 100 may have a pad such as an anode pad, a cathode pad, and a current detection pad. Each pad is arranged in a region close to the end side 162. The region close to the end side 162 refers to a region between the end side 162 and the emitter electrode in the top view. When the semiconductor device 100 is mounted, each pad may be connected to an external circuit via a wiring such as a wire.

The gate voltage is applied to the gate pad 112. The gate pad 112 is electrically connected to a conductive portion of a gate trench portion of the active portion 160. The semiconductor device 100 includes the gate runner that connects the gate pad 112 and the gate trench portion. In FIG. 1, the gate runner is hatched with diagonal lines.

The gate runner of this example has a peripheral gate runner 130 and an active gate runner 131. The peripheral gate runner 130 is disposed between the active portion 160 and the end side 162 of the semiconductor substrate 10 in a top view. In this example, the peripheral gate runner 130 surrounds the active portion 160 in a top view. A region surrounded by the peripheral gate runner 130 in a top view may be the active portion 160. Also, the well region is formed below the gate runner. The well region is a p type region having a higher concentration than a base region described later and is formed from an upper surface of the semiconductor substrate 10 to a position deeper than the base region. A region surrounded by the well region in a top view may be the active portion 160.

The peripheral gate runner 130 is connected to the gate pad 112. The peripheral gate runner 130 is disposed above the semiconductor substrate 10. The peripheral gate runner 130 may be a stack of a metal containing aluminum or the like and polysilicon or may be a wiring made only of metal.

The active gate runner 131 is provided in the active portion 160. The active gate runner 131 may be the metal wiring containing aluminum or the like. The peripheral gate runner 130 and the active gate runner 131 are connected to the gate trench portion of the active portion 160. By providing the active gate runner 131 in the active portion 160, variation in wiring length from the gate pad 112 for each region of the semiconductor substrate 10 can be reduced. The peripheral gate runner 130 and the active gate runner 131 are disposed above the upper surface of the semiconductor substrate 10.

The active gate runner 131 of this example includes a first active gate runner 131-1 and a second active gate runner 131-2. The first active gate runner 131-1 and the second active gate runner 131-2 extend in a second direction above the upper surface of the semiconductor substrate 10. The first active gate runner 131-1 and the second active gate runner 131-2 are provided apart from each other in the second direction. The spaced region described later is provided between the first active gate runner 131-1 and the second active gate runner 131-2 in the second direction. The second direction in this example is the X axis direction.

The active gate runner 131 may be connected to the peripheral gate runner 130. The first active gate runner 131-1 of this example is provided so as to extend in the second direction from one of the two peripheral gate runners 130 sandwiching the active portion 160 in the X axis direction toward the center of the active portion 160. The second active gate runner 131-2 of this example is provided so as to extend in the second direction from another of the two peripheral gate runners 130 sandwiching the active portion 160 in the X axis direction toward the center of the active portion 160.

The semiconductor device 100 may include, though neither is illustrated, a temperature sense portion that is the pn junction diode formed of polysilicon or the like described later, and a current detection section that simulates operation of the transistor portion provided in the active portion 160.

The semiconductor device 100 of this example includes an edge termination structure portion 90 between the active portion 160 and the end side 162 in the top view. The edge termination structure portion 90 of this example is disposed between the peripheral gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

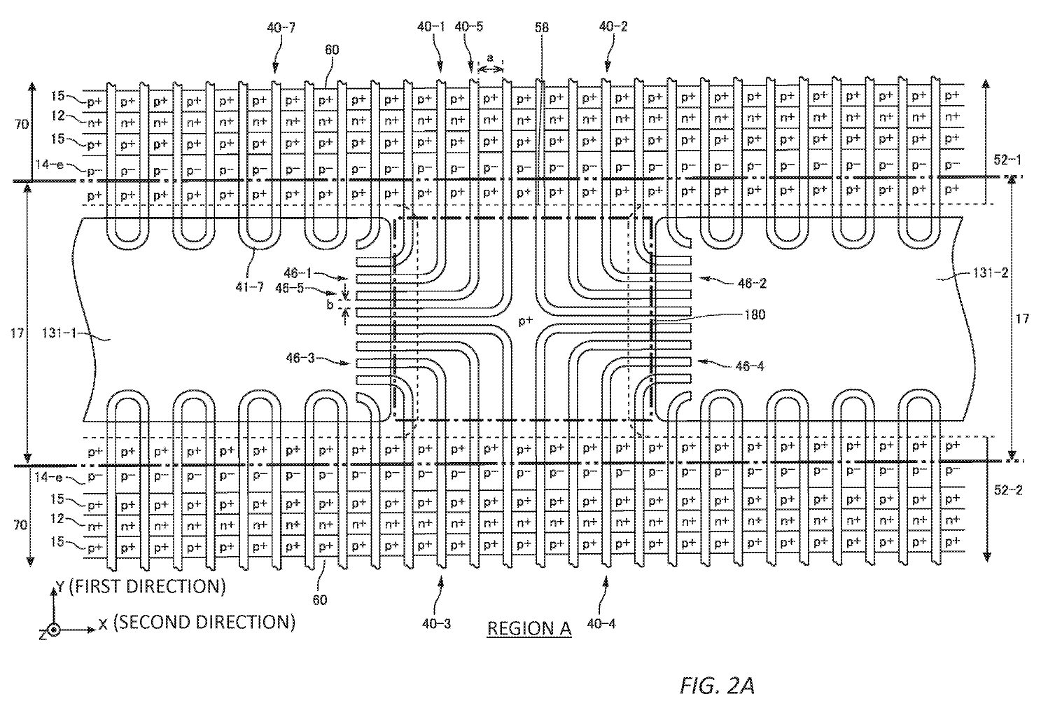

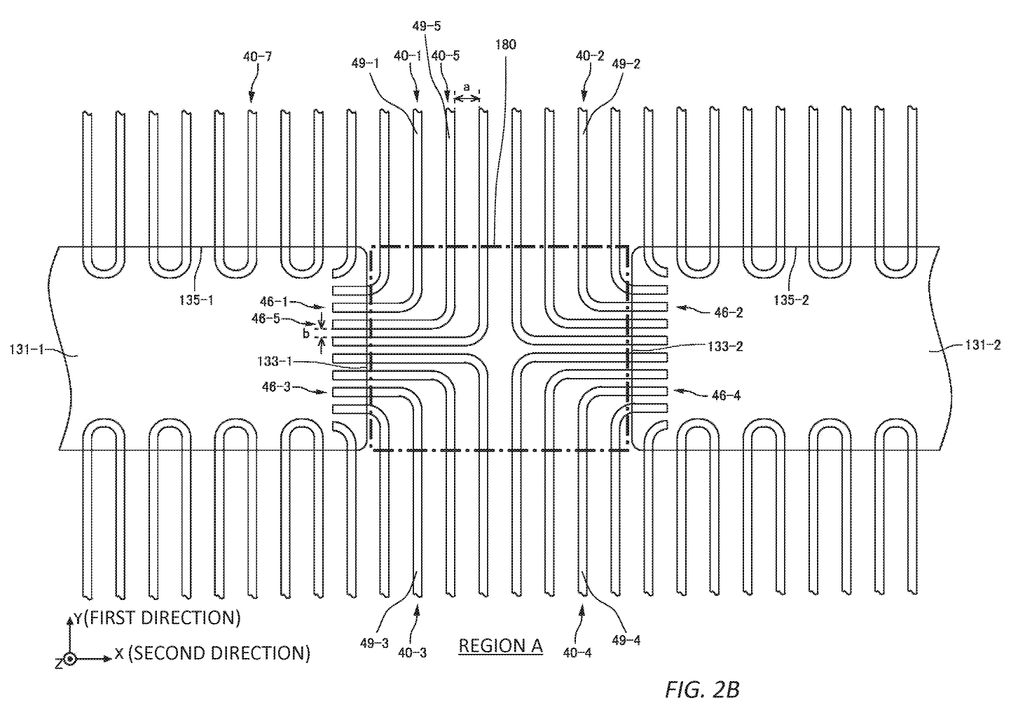

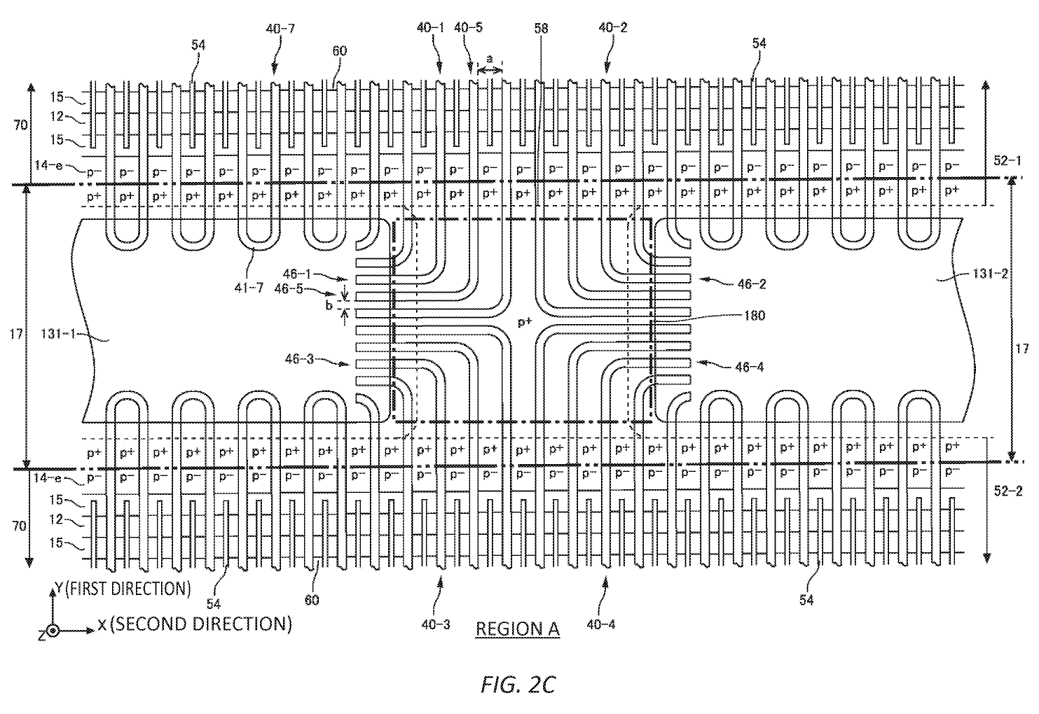

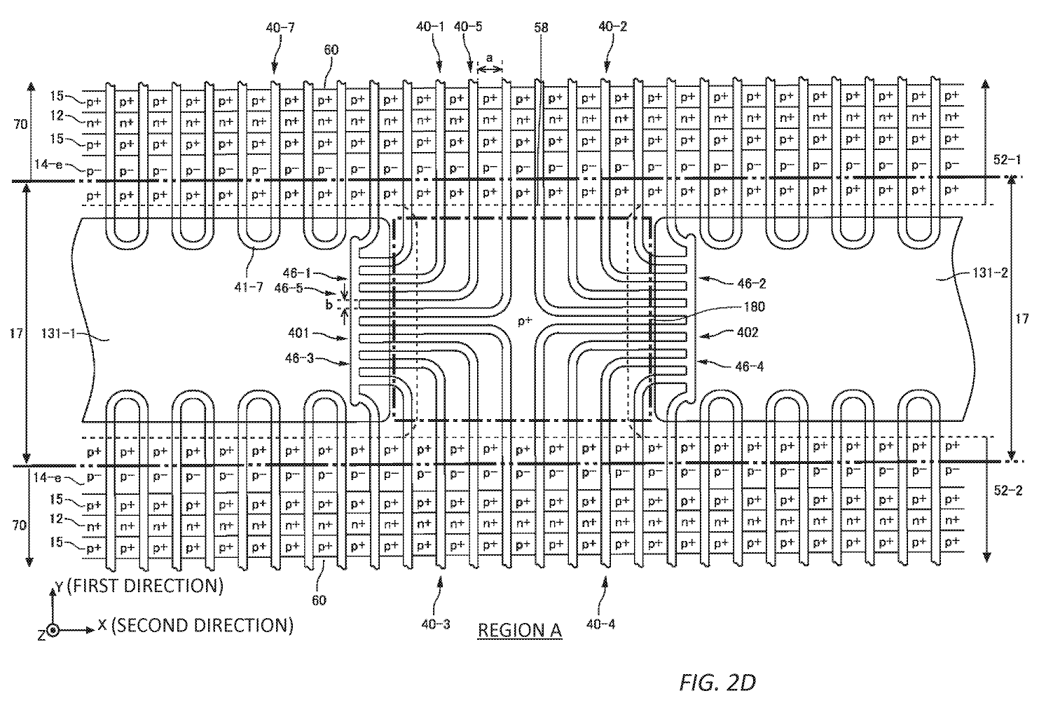

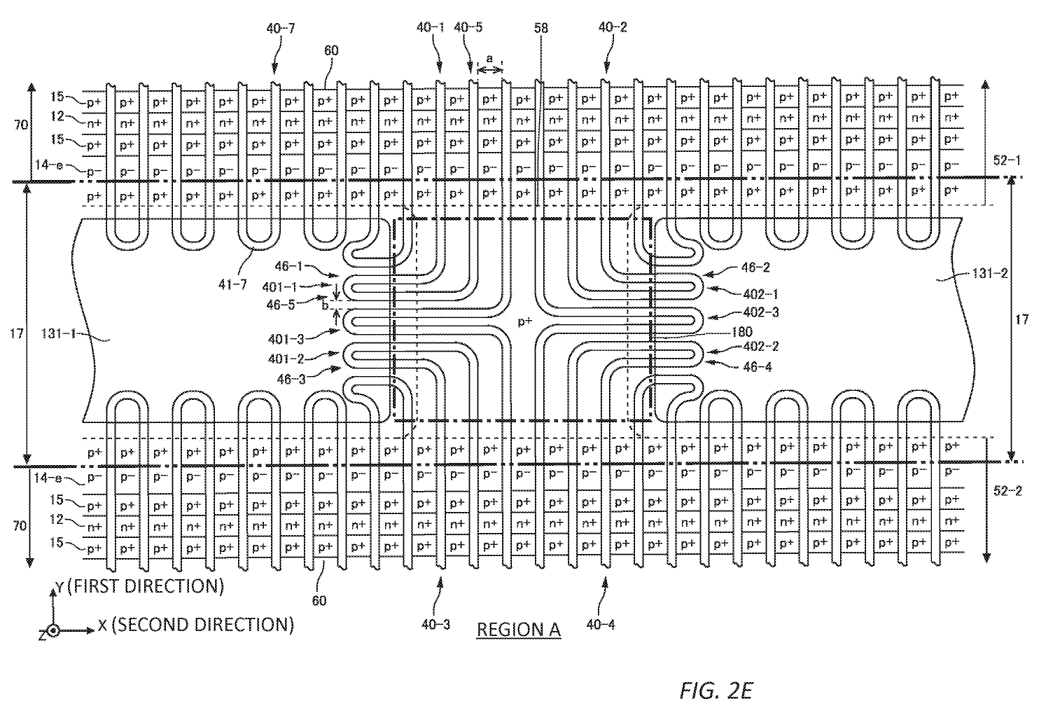

FIG. 2 illustrates an enlarged view of a region A in FIG. 1. In the region A, the first active gate runner 131-1 and the second active gate runner 131-2 are provided apart from each other in the X axis direction. The spaced region 180 is a region between an end portion of the first active gate runner 131-1 on the second active gate runner 131-2 side and an end portion of the second active gate runner 131-2 on the first active gate runner 131-1 side in the X axis direction. The region A includes the transistor portion 70, the first active gate runner 131-1, the second active gate runner 131-2, and the spaced region 180. In FIG. 2A and subsequent drawings, the spaced region 180 is indicated by a dashed-and-dotted line. The spaced region 180 will be described later.

The semiconductor device 100 of this example includes the trench portion, the well region 17, the emitter region 12, the base region 14, and the contact region 15 provided inside the upper surface side of the semiconductor substrate 10. The semiconductor device 100 of this example further includes an emitter electrode 52 and the active gate runner 131 provided above the upper surface of the semiconductor substrate 10. The emitter electrode 52 and the active gate runner 131 are provided separately from each other.

The semiconductor device 100 of this example includes, as the emitter electrode 52, a first emitter electrode 52-1 and a second emitter electrode 52-2. The first emitter electrode 52-1 and the second emitter electrode 52-2 are arranged to face each other with the first active gate runner 131-1, the second active gate runner 131-2, and the spaced region 180 interposed therebetween in the first direction. The first direction intersects the second direction. The first direction in this example is the Y axis direction. That is, the first direction and the second direction may be orthogonal to each other. An interlayer dielectric film is provided between the emitter electrode 52 and the active gate runner 131 and the upper surface of the semiconductor substrate 10, but it is omitted in FIG. 2A.

The emitter electrode 52 is provided above the gate trench portion 40, the well region 17, the emitter region 12, the base region 14, and the contact region 15. In FIG. 2A, the range in which the emitter electrode 52 is provided is indicated by a dotted line. That is, the first emitter electrode 52-1 is provided on the positive side in the Y axis direction relative to the active gate runner 131, and the second emitter electrode 52-2 is provided on the negative side in the Y axis direction relative to the active gate runner 131. The emitter electrode 52 contacts the emitter region 12, the contact region 15, and the base region 14 on the upper surface of the semiconductor substrate 10 through contact holes, but the contact holes are omitted in FIG. 2A.

The semiconductor device 100 has a bridge electrode portion 58 that connects the first emitter electrode 52-1 and the second emitter electrode 52-2. The bridge electrode portion 58 is provided in the spaced region 180. The first active gate runner 131-1 and the second active gate runner 131-2 are not connected to the bridge electrode portion 58. The bridge electrode portion 58 sets the first emitter electrode 52-1 and the second emitter electrode 52-2 to the same potential.

By the bridge electrode portion 58, the inductance between the first emitter electrode 52-1 and the second emitter electrode 52-2 can be reduced. When there is no bridge electrode portion 58, the first emitter electrode 52-1 and the second emitter electrode 52-2 are electrically connected via an external terminal such as a bonding wire. Therefore, the inductance between the first emitter electrode 52-1 and the second emitter electrode 52-2 increase, a slight difference occurs in each potential, a slight delay (imbalance) occurs in the current, and oscillation may occur in the current waveform. On the other hand, when the first emitter electrode 52-1 and the second emitter electrode 52-2 are connected by the bridge electrode portion 58, the inductance between the first emitter electrode 52-1 and the second emitter electrode 52-2 becomes low. As a result, the current imbalance between the first emitter electrode 52-1 and the second emitter electrode 52-2 can be reduced, and thus oscillation of the current waveform can be suppressed.

The emitter electrode 52 is formed of a material including a metal. For example, at least a part of a region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 17 is provided so as to overlap the active gate runner 131. The well region 17 is also provided so as to extend with a predetermined width in a range that does not overlap the active gate runner 131. In this example, the well region 17 is provided from a region overlapping the active gate runner 131 to a region overlapping the emitter electrode 52. The well region 17 is a second conductivity type region in which the doping concentration is higher than the base region 14. In this example, the base region 14 is p- type, and the well region 17 is p+ type.

The semiconductor device 100 includes a plurality of trench portions provided from an upper surface of the semiconductor substrate 10 toward the inside and extending in a first direction on the upper surface. The plurality of trench portions include the plurality of gate trench portions 40. In this example, the plurality of gate trench portions 40 are arranged at intervals from each other along the second direction. The gate voltage is transmitted from the gate pad 112 to the gate trench portion 40.

In this example, the plurality of trench portions include the seventh gate trench portion 40-7 facing the first active gate runner 131-1 in the first direction. The seventh gate trench portion 40-7 extends in the first direction to below the first active gate runner 131-1 and is connected to the first active gate runner 131-1. The active gate runner 131 is connected to the gate trench portion 40 through a contact hole provided in an interlayer dielectric film.

In this example, the seventh gate trench portion 40-7 has two extending portions (portions of the trenches that are linear along the extending direction) extending along the first direction and the tip portion 41-7 connecting the two extending portions. It is preferable that at least a part of the tip portion 41-7 is provided in the curved shape in a top view. By the tip portion 41-7 connecting the end portions of the two extending portions in the first direction, electric field strength at the end portions of the extending portions can be reduced. Other gate trench portions 40 facing the second active gate runner 131-2 in the first direction may be the same.

The diffusion depth of the well region 17 may be deeper than the depth of the gate trench portion 40. An end portion of the gate trench portion 40 is provided in the well region 17 in a top view. In other words, at an end portion of each trench portion, the bottom portion in the depth direction of each trench portion is covered with the well region 17. With this configuration, the electric field strength on the bottom portion of each trench portion can be reduced. In FIG. 2A and the subsequent drawings, the range in which the well region 17 is provided is indicated by a two-dot chain line. In this example, the spaced region 180 is included in the well region 17 in the top view.

A mesa portion 60 is provided between the respective trench portions in the array direction. The mesa portion 60 refers to a region sandwiched between the trench portions inside the semiconductor substrate 10. As an example, an upper end of the mesa portion 60 is the upper surface of the semiconductor substrate 10. The depth position of the lower end of the mesa portion 60 is the same as the depth position of the lower end of the trench portion. The mesa portion 60 of this example is provided on the upper surface of the semiconductor substrate 10 so as to extend along the trench in the first direction. The mesa portion 60 of this example is provided in the transistor portion 70.

Each mesa portion 60 is provided with the base region 14. Among the base region 14 exposed on the upper surface of the semiconductor substrate 10 in the mesa portion 60, the region arranged closest to the active gate runner 131 is referred to as a base region 14-e. FIG. 2A illustrates the base region 14-e arranged at one end portion in the extending direction of each mesa portion 60, but the base region 14-e is also arranged at another end portion of each mesa portion 60.

In each mesa portion 60, at least one of the emitter region 12 of a first conductivity type or the contact region 15 of a second conductivity type may be provided in a region sandwiched by the base region 14-e in a top view. The emitter region 12 of this example is n+ type, and the contact region 15 is p+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to the other trench portion in the X axis direction. As an example, the contact region 15 and the emitter region 12 in the mesa portion 60 are alternately arranged along the extending direction of the trench portion (the first direction).

In another example, the contact region 15 and the emitter region 12 in the mesa portion 60 may be provided in a stripe shape along the extending direction of the trench portion. For example, the emitter region 12 is provided in a region in contact with the trench portion, and the contact region 15 is provided in a region sandwiched between the emitter regions 12.

The contact hole is provided above each mesa portion. The contact hole is arranged in the region sandwiched between the base regions 14-e. The contact holes are provided above the respective regions of the contact region 15, the base region 14, and the emitter region 12. However, in FIG. 2A, illustration of the contact holes is omitted. The contact hole is not provided in regions corresponding to the base region 14-e and the well region 17. The contact hole may be arranged at the center of the mesa portion 60 in the array direction (the X axis direction).

The plurality of trench portions have the first gate trench portion 40-1. The first gate trench portion 40-1 has the first extending portion and the first connection portion 46-1. The first extending portion extends in a first direction to the spaced region 180 between the first active gate runner 131-1 and the second active gate runner 131-2. The first connection portion 46-1 is provided in the spaced region 180 and connects the first extending portion to the first active gate runner 131-1. The first extending portion will be described later.

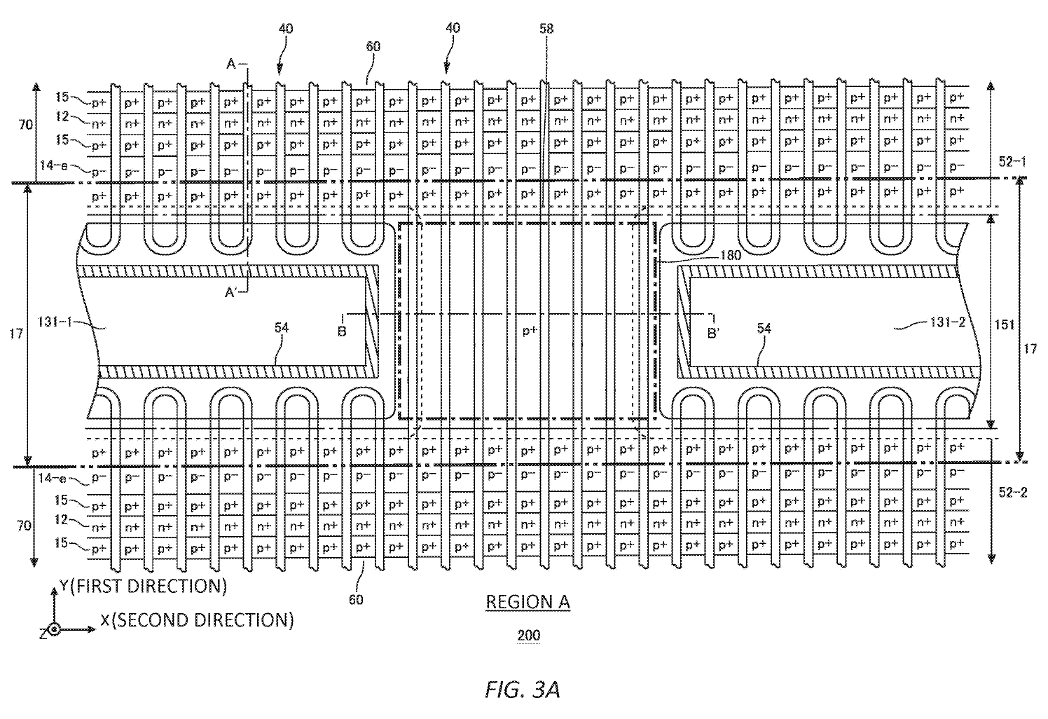

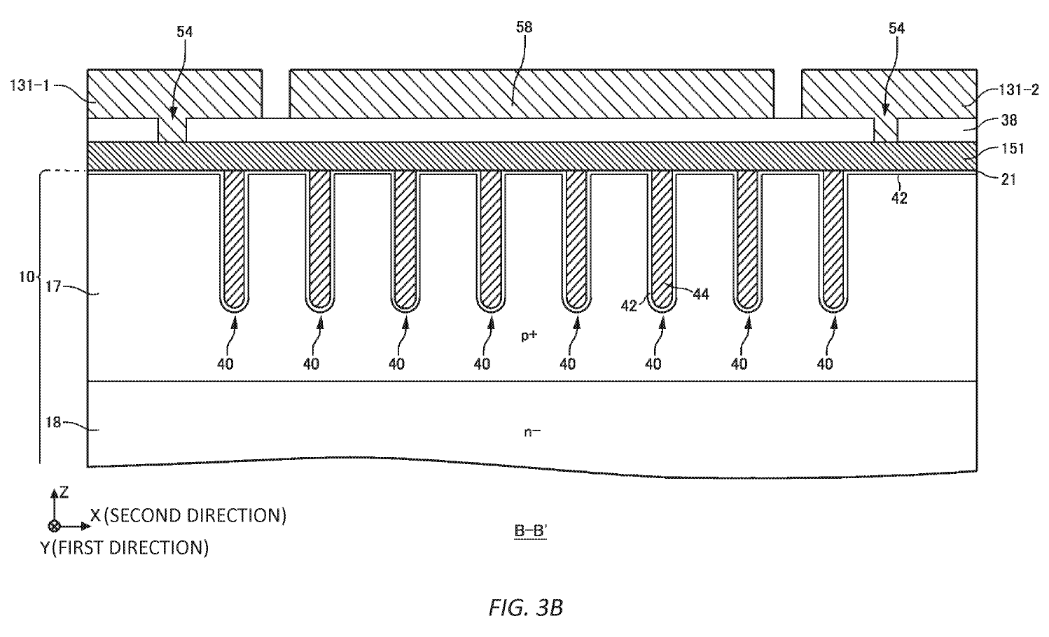

With such a configuration, the gate voltage is directly transmitted from the first active gate runner 131-1 to the gate conductive portion of the first gate trench portion 40 without passing through the polysilicon runner. The polysilicon runner is, the planar polysilicon layer formed above the upper surface 21 of the semiconductor substrate 10 and transmits a gate signal to the gate conductive portion of each gate trench portion 40. With the configuration of this example, it is possible to suppress a transmission delay of the gate voltage peculiar to the polysilicon runner and prevent a reduction in withstand capability due to current imbalance at turn-off. The polysilicon runner is, for example, the polysilicon layer described later in FIGS. 3A and 3B. The first gate trench portion 40 may be the trench portion facing the spaced region 180 in the first direction. The first gate trench portion 40-1 is a trench portion in which a distance to the first active gate runner 131-1 is smaller than a distance to the second active gate runner 131-2. In other words, the first gate trench portion 40-1 is the trench portion arranged near the first active gate runner 131-1.

FIG. 2B is a diagram for explaining the spaced region 180. FIG. 2B illustrates the region A, as does FIG. 2A. However, in FIG. 2B, illustration of the respective regions of the well region 17, the emitter region 12, the base region 14, and the contact region 15, and of the emitter electrode 52 is omitted. The spaced region 180 is a region between the first active gate runner 131-1 and the second active gate runner 131-2 in the second direction. In FIG. 2B, the spaced region 180 is indicated by a dashed-and-dotted line. The spaced region 180 may be provided at the center of the active portion 160 in the second direction.

The width of the spaced region 180 in the second direction may be equal to the distance between the first active gate runner 131-1 and the second active gate runner 131-2 in the second direction. The width of the spaced region 180 in the first direction may be the length at which the first active gate runner 131-1 and the second active gate runner 131-2 overlap in the second direction. In this example, the width of the spaced region 180 in the first direction is equal to the width of the first active gate runner 131-1 in the first direction and is also equal to the width of the second active gate runner 131-2.

FIG. 2B illustrates the first extending portion 49-1 of the first gate trench portion 40-1. As described above, the first extending portion 49-1 extends in the first direction to the spaced region 180. The first extending portion 49-1 may extend in the first direction from below the first emitter electrode 52-1 to the spaced region 180.

The first connection portion 46-1 connects the first extending portion 49-1 and the first active gate runner 131-1 in the spaced region 180. The first connection portion 46-1 may extend in the second direction. The first connection portion 46-1 has a portion that connects to the first extending portion 49-1 and that may be curved in top view. In this case, the side wall of the first gate trench portion 40-1 at the portion connected to the first extending portion 49-1 has the curved-surface shape. The first connection portion 46-1 may be provided so as to intersect the first end side 133-1 of the first active gate runner 131-1.

The plurality of trench portions may include the second gate trench portion 40-2. The second gate trench portion 40-2 is the trench portion in which a distance to the second active gate runner 131-2 is smaller than a distance to the first active gate runner 131-1. That is, the second gate trench portion 40-2 is the trench portion disposed near the second active gate runner 131-2.

The second gate trench portion 40-2 has the second extending portion 49-2 and the second connection portion 46-2. The second extending portion 49-2 extends in the first direction to the spaced region 180. The second connection portion 46-2 is provided in the spaced region 180 and connects the second extending portion 49-2 to the second active gate runner 131-2. The second connection portion 46-2 may extend in the second direction. The second connection portion 46-2 has a portion that connects to the second extending portion 49-2 and that may be curved in top view. In this case, the side wall of the second gate trench portion 40-2 at the portion connected to the second extending portion 49-2 has the curved-surface shape. The second connection portion 46-2 may be provided so as to intersect the second end side 133-2, which will be described later, of the second active gate runner 131-2.

The first gate trench portion 40-1 and the second gate trench portion 40-2 may extend in the first direction from below the first emitter electrode 52-1 to the spaced region 180. In this example, the first extending portion 49-1 and the second extending portion 49-2 extend in the first direction from below the first emitter electrode 52-1 (in the direction toward the lower surface 23) to the spaced region 180.

The plurality of trench portions may include a third gate trench portion 40-3. The third gate trench portion 40-3 is the trench portion in which a distance to the first active gate runner 131-1 is smaller than a distance to the second active gate runner 131-2. That is, the third gate trench portion 40-3 is the trench portion disposed near the first active gate runner 131-1.

The third gate trench portion 40-3 has the third extending portion 49-3 and the third connection portion 46-3. The third extending portion 49-3 extends in the first direction from below the second emitter electrode 52-2 to the spaced region 180. The third connection portion 46-3 is provided in the spaced region 180 and connects the third extending portion 49-3 to the first active gate runner 131-1. The third connection portion 46-3 may extend in the second direction. The third connection portion 46-3 has a portion that connects to the third extending portion 49-3 and that may be curved in top view. In this case, the side wall of the third gate trench portion 40-3 at the portion that connects to the third extending portion 49-3 has the curved-surface shape. The third connection portion 46-3 may be provided so as to intersect the second end side 133-2, which will be described later, of the second active gate runner 131-2.

The plurality of trench portions may include the fourth gate trench portion 40-4. The fourth gate trench portion 40-4 is a trench portion in which the distance to the second active gate runner 131-2 is smaller than the distance to the first active gate runner 131-1. That is, the fourth gate trench portion 40-4 is the trench portion disposed near the second active gate runner 131-2.

The fourth gate trench portion 40-4 has a fourth extending portion 49-4 and a fourth connection portion 46-4. The fourth extending portion 49-4 extends in the first direction from below the second emitter electrode 52-2 to the spaced region 180. The fourth connection portion 46-4 is provided in the spaced region 180 and connects the fourth extending portion 49-4 to the second active gate runner 131-2. The fourth connection portion 46-4 may extend in the second direction. The fourth connection portion 46-4 has a portion that connects to the fourth extending portion 49-4 and that may be curved in top view. In this case, the side wall of the fourth gate trench portion 40-4 at the portion that connects to the fourth extending portion 49-4 has the curved-surface shape. The fourth connection portion 46-4 may be provided so as to intersect the second end side 133-2, which will be described later, of the second active gate runner 131-2.

The plurality of trench portions may include a fifth gate trench portion 40-5. The fifth gate trench portion 40-5 may refer to any of the plurality of first gate trench portions 40-1. As described above, the first gate trench portion 40-1 is the trench portion that faces the spaced region 180 in the first direction and that has the distance to the first active gate runner 131-1 smaller than the distance to the second active gate runner 131-2. Therefore, the fifth gate trench portion 40-5 is a trench portion in which the distance to the first active gate runner 131-1 is smaller than a distance to the second active gate runner 131-2. That is, the fifth gate trench portion 40-5 is the trench portion disposed near the first active gate runner 131-1. The fifth gate trench portion 40-5 is disposed farther from the first active gate runner 131-1 in the second direction than any of the first gate trench portions 40-1. That is, of the two first gate trench portions 40-1 arranged in the second direction, one closer to the first active gate runner 131-1 may be the first gate trench portion 40-1, and another farther away may be the fifth gate trench portion 40-5. Unless otherwise specifically described, the fifth gate trench portion 40-5 may be treated as the first gate trench portion 40-1.

The fifth gate trench portion 40-5 has the fifth extending portion 49-5 and the fifth connection portion 46-5. The fifth extending portion 49-5 extends in the first direction to the spaced region 180. The fifth connection portion 46-5 is provided in the spaced region 180 and connects the fifth extending portion 49-5 to the first active gate runner 131-1. In this example, the fifth extending portion 49-5 extends farther inward in the spaced region 180 in the first direction than the first extending portion 49-1. With such a configuration, a plurality of trench portions facing the spaced region 180 can be connected to the same active gate runner 131, and gate delay can be suppressed.

The fifth gate trench portion 40-5 may extend in the first direction from below the first emitter electrode 52-1 to the spaced region 180. In this example, the fifth extending portion 49-5 extends in the first direction from below the first emitter electrode 52-1 to the spaced region 180.

In the semiconductor device 100 of this example, the gate trench portion 40 corresponding to the fifth gate trench portion 40-5 in the first gate trench portion 40-1 is also provided in the second gate trench portion 40-2. In other words, a plurality of second gate trench portions 40-2 are provided. The same applies to the third gate trench portion 40-3 and the fourth gate trench portion 40-4.

An interval in the second direction between the plurality of trench portions extending in the first direction to the spaced region 180 is defined as the interval a. The interval a may be an interval between the extending portions 49 of the plurality of adjacent trench portions. Also, an interval in the first direction between the plurality of trench portions in the spaced region 180 is defined as the interval b. The interval b may be an interval between the connection portions 46 of the plurality of adjacent trench portions. The interval a and the interval b may satisfy the following relationship:
0.01 < b/a < 1.

The interval a is the width of the mesa portion in the active portion 160, and a predetermined width is necessary to form the emitter region 12 and the contact region 15. On the other hand, the interval b may be smaller than the interval a because the emitter region 12 and the contact region 15 are not formed. That is, the emitter region 12 and the contact region 15 need not be formed between the connection portions 46 of the plurality of adjacent trench portions. Here, b/a may be 0.05 or more and 0.5 or less and may be 0.08 or more and 0.2 or less. When the plurality of trench portions includes dummy trench portions described later, the interval a may be an interval between adjacent gate trench portions 40 and dummy trench portions.

In a top view, the first active gate runner 131-1 has the first end side 133-1. In a top view, the second active gate runner 131-2 has the second end side 133-2 facing the first end side 133-1 in the second direction. The first end side 133-1 and the second end side 133-2 may be, among the linear end sides of the respective active gate runners 131, the end sides having the shortest length. In this example, the first end side 133-1 and the second end side 133-2 are parallel to the first direction. The first end side 133-1 and the second end side 133-2 may be end sides of the spaced region 180 in the second direction.

In a top view, the first active gate runner 131-1 has a first long side 135-1. In a top view, the second active gate runner 131-2 has a second long side 135-2. Each long side may be the straight end side having the longest length among the end sides of each active gate runner 131. Each long side may be parallel to the second direction. The first active gate runner 131-1 in this example has the two first long sides 135-1 facing each other. The second active gate runner 131-2 in this example has the two-second-long sides 135-2 facing each other. The first long side 135-1 and the second long side 135-2 may define ends of the spaced region 180 in the first direction. The seventh gate trench portion 40-7 in this example extends in the first direction and intersects the first long side 135-1.

In the spaced region 180, the polysilicon gate runner connecting the first active gate runner 131-1 and the second active gate runner 131-2 need not be provided. As described above, the first gate trench portion 40-1 in this example extends to a portion overlapping the first active gate runner 131. Similarly, the second gate trench portion 40-2 to the fifth gate trench portion 40-5 also extend to a position overlapping any of the active gate runners 131. For this reason, even if a polysilicon gate runner is not provided in the spaced region 180, the first gate trench portion 40-1 to the fifth gate trench portion 40-5 and the active gate runner 131 can be connected. In addition, by directly connecting the first gate trench portion 40-1 to the fifth gate trench portion 40-5 and the active gate runner 131, the transmission delay of the gate voltage can be reduced.

FIG. 2C is a diagram illustrating an example of the arrangement of the contact hole 54 in the region A. The contact hole 54 is provided in the interlayer dielectric film above each mesa portion 60. The contact hole connects the emitter region 12 and the contact region 15 to the emitter electrode 52. In the region A, the contact hole 54 is provided above the emitter region 12 and the contact region 15 and is not provided above the base region 14 and the well region 17. The contact hole 54 in this example extends in the first direction. An end of the contact hole 54 in the first direction is located above the contact region 15 in contact with the base region 14-e in the first direction. The contact hole 54 is also provided in the mesa portion 60 facing the spaced region 180 in the first direction, but the contact hole 54 in this example is not provided in the spaced region 180.

FIG. 2D is a diagram illustrating another example of the trench portion in the region A. FIG. 2D differs from FIG. 2A in that the semiconductor device 100 has the trench connection portion 401 and the trench connection portion 402. The semiconductor device 100 may have the trench connection portion that connects the plurality of connection portions 46 to each other. The semiconductor device 100 may have a first trench connection portion that connects the plurality of first connection portions 46-1 to each other. The plurality of first connection portions 46-1 refer to the first connection portion 46-1 of each of the first gate trench portions 40-1 when the plurality of first gate trench portions 40-1 are provided.

The semiconductor device 100 may have a second trench connection portion that connects the plurality of second connection portions 46-2 to each other. The plurality of second connection portions 46-2 refer to the second connection portion 46-2 of each of the second gate trench portions 40-2 when the plurality of second gate trench portions 40-2 are provided.

The semiconductor device 100 may have a third trench connection portion that connects the plurality of third connection portions 46-3 to each other. The plurality of third connection portions 46-3 refer to the third connection portion 46-3 of each of the third gate trench portions 40-3 when the plurality of third gate trench portions 40-3 are provided.

The semiconductor device 100 may have the fourth trench connection portion that connects the first connection portion 46-1 and the third connection portion 46-3 to each other. The semiconductor device 100 may have a fifth trench connection portion that connects the plurality of fourth connection portions 46-4 to each other. The plurality of fourth connection portions 46-4 refer to the fourth connection portion 46-4 of each of the fourth gate trench portions 40-4 when the plurality of fourth gate trench portions 40-4 are provided. In FIG. 2D, for example, the trench portion adjacent to the fourth gate trench portion 40-4 may also be regarded as the fourth gate trench portion 40-4. The semiconductor device 100 may have a sixth trench connection portion that connects the second connection portion 46-2 and the fourth connection portion 46-4 to each other.

The trench connection portion 401 of this example is an example of the first trench connection portion, the third trench connection portion, and the fourth trench connection portion. The trench connection portion 401 of this example connects each of the plurality of first connection portions 46-1 and the plurality of third connection portions 46-3 which are connected to the first active gate runner 131-1. The trench connection portion 402 of this example is an example of the second trench connection portion, the fifth trench connection portion, and the sixth trench connection portion. The trench connection portion 402 of this example connects each of the plurality of second connection portions 46-2 and the plurality of fourth connection portions 46-4 which are connected to the second active gate runner 131-2.

The trench connection portion 401 and the trench connection portion 402 may be the gate trench portions 40. By respectively connecting the ends of the plurality of gate trench portions 40 by the trench connection portion 401 and the trench connection portion 402, isolated ends of the gate trench portion 40 are eliminated. As a result, it is possible to suppress formation defects of the gate oxide film in the trench portion having an end as a single piece, and to suppress a decrease in the withstand voltage of the gate oxide film. The trench connection portion 401 and the trench connection portion 402 may be connected to the seventh gate trench portion 40.

FIG. 2E is a diagram illustrating another example of the trench portion in the region A. In FIG. 2E, the shapes of the trench connection portion 401 and the trench connection portion 402 are different from those in FIG. 2D. The semiconductor device 100 of this example includes the plurality of trench connection portions 401 (the trench connection portion 401-1, the trench connection portion 401-2, and a trench connection portion 401-3) and the plurality of trench connection portions 402 (the trench connection portion 402-1, the trench connection portion 402-2, and a trench connection portion 402-3). The trench connection portion 401-1 of this example is an example of the first trench connection portion. In FIG. 2E, the trench connection portion 401-1 connects the two adjacent first connection portions 46-1 among the plurality of first connection portions 46-1 connected to the first active gate runner 131-1 to each other. The trench connection portion 401-2 of this example is an example of the third trench connection portion. In FIG. 2E, the trench connection portion 401-2 connects the two adjacent third connection portions 46-3 among the plurality of third connection portions 46-3 connected to the first active gate runner 131-1 to each other. The trench connection portion 401-3 in this example is an example of the fourth trench connection portion. In FIG. 2E, the trench connection portion 401-3 connects the first connection portion 46-1 and the third connection portion 46-3 which are connected to the first active gate runner 131-1. Each trench connection portion 401 in this example is arc-shaped.

The trench connection portion 402-1 in this example is an example of the second trench connection portion. In FIG. 2E, the trench connection portion 402-1 connects the two adjacent second connection portions 46-2 among the plurality of second connection portions 46-2 connected to the second active gate runner 131-2. The trench connection portion 402-2 in this example is an example of the fifth trench connection portion. In FIG. 2E, the trench connection portion 402-2 connects the two adjacent fourth connection portions 46-4 among the plurality of fourth connection portions 46-4 connected to the second active gate runner 131-2. The trench connection portion 402-3 in this example is an example of the sixth trench connection portion. In FIG. 2E, the trench connection portion 402-3 connects the second connection portion 46-2 and the fourth connection portion 46-4 which are connected to the second active gate runner 131-2. Each trench connection portion 402 in this example is arc-shaped.

The trench connection portion 401 and the trench connection portion 402 may be the gate trench portions 40. By connecting the ends of the plurality of gate trench portions 40 with the trench connection portion 401 and the trench connection portion 402, isolated ends of the gate trench portion 40 are eliminated. Furthermore, by making the trench connection portion arc-shaped, mechanical and electrical stress on the gate oxide film can be further reduced. This makes it possible to suppress formation defects of the gate oxide film in the trench portion having an end as a single piece, and to suppress a decrease in the withstand voltage of the gate oxide film.

FIG. 3A is a diagram illustrating the region A of the semiconductor device 200 in a comparative example. In the semiconductor device 200, the polysilicon layer 151 is provided between the upper surface of the semiconductor substrate 10 and the active gate runner 131. In other words, the gate runner crossing the active portion 160 is the stack of polysilicon and metal. The polysilicon layer 151 is also provided above the spaced region 180. In the semiconductor device 200, the contact hole 54 connecting the first active gate runner 131-1 and the polysilicon layer 151 is formed. Similarly, the contact hole 54 connecting the second active gate runner 131-2 and the polysilicon layer 151 is formed.

FIG. 3B is a diagram illustrating the cross section B-B' of the semiconductor device 200 shown in FIG. 3A. In FIG. 3B, only the upper surface 21 side of the semiconductor substrate 10 is illustrated, and the lower surface side is omitted. The semiconductor substrate 10 has the drift region 18 of a first conductivity type.

The well region 17 of the second conductivity type is provided between the drift region 18 and the upper surface 21 of the semiconductor substrate 10. The well region 17 is formed deeper than the gate trench portion 40. Above the upper surface 21 of the semiconductor substrate 10, the polysilicon layer 151 is provided via the gate dielectric film 42. The polysilicon layer 151 is connected at the upper surface 21 to the conductive portion of the gate trench portion 40. The conductive portion may be formed of polysilicon.

Above the polysilicon layer 151, the first active gate runner 131-1, the second active gate runner 131-2, and the bridge electrode portion 58 are provided via an interlayer dielectric film 38. The first active gate runner 131-1 and the second active gate runner 131-2 are connected to the polysilicon layer 151 via contact holes 54 provided in the interlayer dielectric film 38.

In the semiconductor device 200, the gate voltage is transmitted to the gate trench portion 40 around the spaced region 180 from the active gate runner 131 via the polysilicon layer 151. In calculating the resistance value of each point of the gate trench portion 40 in a top view of the semiconductor device 200, the resistance value around the spaced region 180 is the largest. Since the specific resistance of polysilicon is several orders of magnitude greater than the specific resistance of aluminum, it is considered that the magnitude of the transmission delay of the gate voltage around the spaced region 180 is determined by the polysilicon layer 151. That is, transmission delay is particularly likely to occur around the spaced region 180.

The voltage of the gate trench portion 40 rises to a predetermined voltage as the polysilicon layer 151 and the conductive portion of the gate trench portion 40 are charged. Around the spaced region 180 of the semiconductor device 200, charging is performed in order from the gate trench portion 40 closer to the active gate runner 131 in the second direction, and charging of the gate trench portion 40 farther from the active gate runner 131 is delayed. Therefore, gate delay is likely to occur in the gate trench portion 40 farther from the active gate runner 131.

Furthermore, the semiconductor device at the time of gate voltage transmission corresponds to charging the circuit of the time constant RC in which the series resistor (resistance value R) and the capacitor (capacitance C) are connected. In the comparative example, since the polysilicon layer 151 is on the upper surface, the capacitance C is larger than that of the semiconductor device 100 of the example. As for the resistance value R as well, the farther the gate trench portion is from the active gate runner 131, the longer the distance becomes and the larger the resistance value R becomes. Therefore, because both the increase in the capacitance C and the increase in the resistance value R are multiplied, the time constant RC becomes extremely large compared with that of the example.

In the semiconductor device 100 of the example, there is no polysilicon layer 151, and the first gate trench portion 40-1 to the fifth gate trench portion 40-5 are directly connected to the active gate runner 131. Therefore, the resistance value R in each gate trench portion 40 is several orders of magnitude smaller, and the capacitance C is also reduced to be one order of magnitude or more smaller, so that the time constant RC becomes much smaller than that in the comparative example. Therefore, the time required for charging can be shortened to suppress gate delay, and a reduction in withstand capability due to current imbalance at turn-off can be prevented.

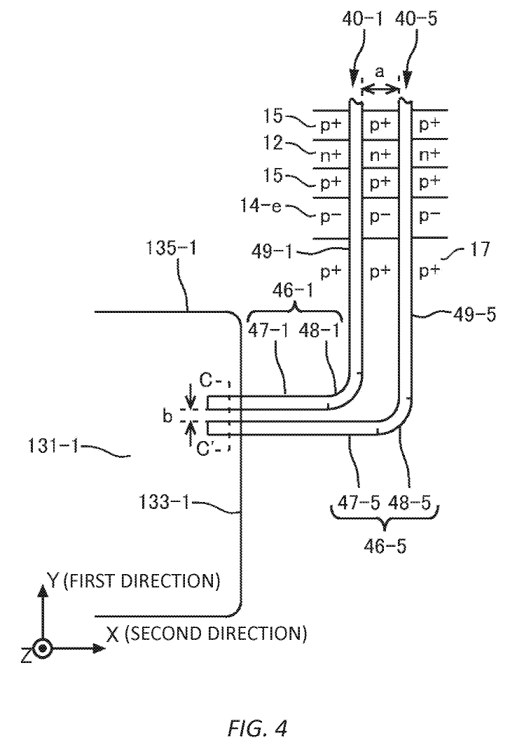

FIG. 4 is the enlarged top view of the region close to the first active gate runner 131-1 in FIG. 2A. In FIG. 4, only the first gate trench portion 40-1 and the fifth gate trench portion 40-5 are illustrated, and the other trench portions are omitted.

The first connection portion 46-1 of this example intersects the first end side 133-1. The first connection portion 46-1 may intersect the first end side 133-1 perpendicularly. That is, the first connection portion 46-1 may extend in the second direction. The first gate trench portion 40-1 need not intersect the first long side 135-1. The fifth connection portion 46-5 also similarly intersects the first end side 133-1.

In this example, the first connection portion 46-1 extends to a portion overlapping the first active gate runner 131-1. The first connection portion 46-1 is connected to the first active gate runner 131-1 at the portion overlapping the first active gate runner 131-1. The fifth connection portion 46-5 also similarly extends to a portion overlapping the first active gate runner 131-1.

The first connection portion 46-1 may have the first straight portion 47-1 extending in the second direction. In this example, the first straight portion 47-1 intersects the first end side 133-1 and extends to a portion overlapping the first active gate runner 131-1. The width of the first straight portion 47-1 and the width of the first extending portion 49-1 may be equal. The first straight portion 47-1 may be entirely provided in the spaced region 180 except for a portion overlapping the first active gate runner 131-1. The fifth connection portion 46-5 may also similarly have the fifth straight portion 47-5 extending in the second direction.

The first connection portion 46-1 may have a first curved portion 48-1 connecting the first straight portion 47-1 and the first extending portion 49-1. This makes it possible to guide the first gate trench portion 40-1 in the direction intersecting the first end side 133-1. The first curved portion 48-1 may be entirely provided in the spaced region 180. The fifth connection portion 46-5 may also similarly have the fifth curved portion 48-5 connecting the fifth straight portion 47-5 and the fifth extending portion 49-5. In FIG. 4, respective boundaries between the extending portions 49 and the curved portions 48 and respective boundaries between the curved portions 48 and the straight portions 47 are indicated by dotted lines.

The other gate trench portions 40 may have a similar configuration. For example, the second connection portion 46-2 may also similarly intersect the second end side 133-2. The second connection portion 46-2 may also similarly have the second straight portion and the second curved portion. The same applies to the third connection portion 46-3 and the fourth connection portion 46-4.

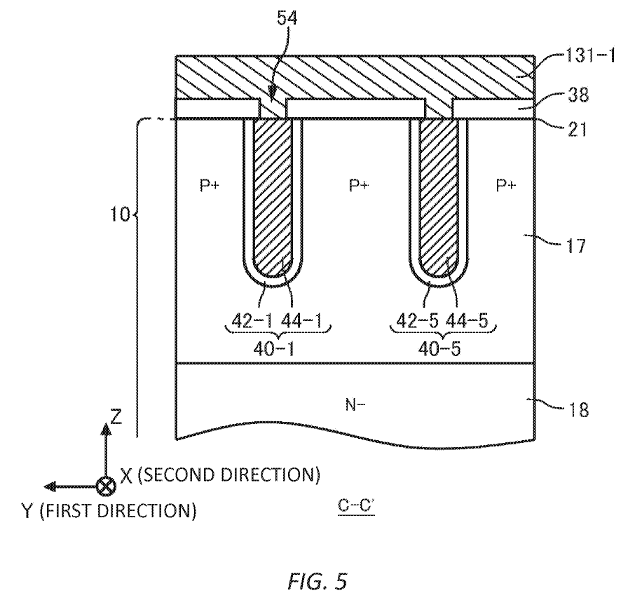

FIG. 5 is a diagram illustrating the cross section C-C' in FIG. 4. The cross-section C-C' is the YZ cross section crossing the first connection portion 46-1 and the fifth connection portion 46-5. In FIG. 5, only the upper surface 21 side of the semiconductor substrate 10 is illustrated.

The semiconductor device 100 includes the semiconductor substrate 10, the interlayer dielectric film 38, and the first active gate runner 131-1 in the cross section C-C'. The semiconductor substrate 10 has the upper surface 21. The drift region 18 and the well region 17 are formed inside the semiconductor substrate 10. The well region 17 is formed between the upper surface 21 of the semiconductor substrate 10 and the drift region 18.

In the semiconductor substrate 10, the plurality of trench portions provided from the upper surface 21 of the semiconductor substrate 10 toward the inside are formed. FIG. 5 illustrates the above-described first gate trench portion 40-1 and fifth gate trench portion 40-5.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The interlayer dielectric film 38 is provided on the upper surface 21 of the semiconductor substrate 10. The first active gate runner 131-1 is provided above the interlayer dielectric film 38. The first active gate runner 131-1 is connected to the gate conductive portion 44 via the contact hole 54 provided in the interlayer dielectric film 38.

The first active gate runner 131-1 may be formed of metal. The first active gate runner 131-1 may be formed only of metal. The same applies to the second active gate runner 131-2.

In this example, no polysilicon gate runner is provided between the first active gate runner 131-1 and the upper surface 21 of the semiconductor substrate 10. The first active gate runner 131-1 need not be a stack of metal and polysilicon. By not providing the polysilicon gate runner, the area of the active portion 160 can be increased as described later.

However, directly above the gate trench portion 40, polysilicon of the gate conductive portion 44 may be formed above the upper surface. In this case, except for directly above the gate trench portion 40, polysilicon need not be provided between the first active gate runner 131-1 and the upper surface 21 of the semiconductor substrate 10.

In the semiconductor device 100 of this example, an upper end of the gate conductive portion 44 is in contact with the first active gate runner 131-1. That is, the first active gate runner 131-1 and the gate conductive portion 44 are in direct contact. The upper end of the gate conductive portion 44 may be flush with the upper surface 21 of the semiconductor substrate 10 and may be disposed below the upper surface 21. The same may apply to the second active gate runner 131-2.

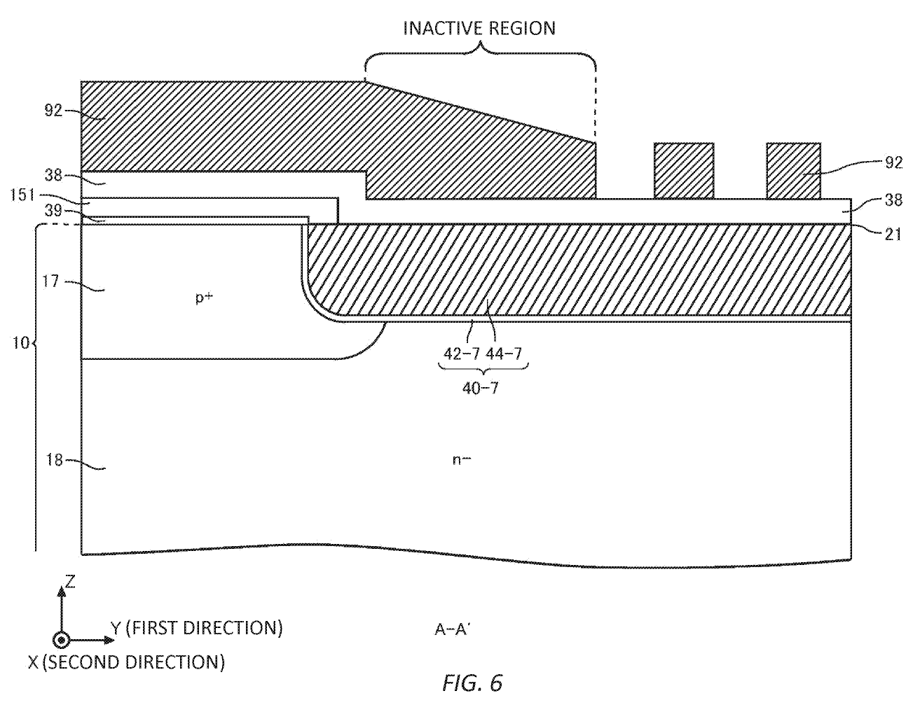

FIG. 6 is a diagram for explaining the inactive region formed in the manufacturing process of the semiconductor device 200 of the comparative example. FIG. 6 corresponds to the cross section A-A' that crosses the seventh gate trench portion 40-7 in FIG. 3A in the first direction. However, FIG. 6 is the cross-sectional view of the step of forming the emitter region 12 of the semiconductor device 200.

The semiconductor device 200 illustrated in FIG. 6 includes the polysilicon layer 151 above the upper surface 21. The polysilicon layer 151 is provided above the dielectric film 39. The dielectric film 39 may be a natural oxide film and may be one in which the gate dielectric film 42 is extended. The interlayer dielectric film 38 is provided above the polysilicon layer 151 and above the upper surface 21.

The resist 92 for forming the emitter region 12 is formed above the interlayer dielectric film 38. However, the resist 92 has an inclination formed due to the polysilicon layer 151. When there is an inclination, there is a concern that the opening width of the resist 92 varies, and thus the dimensions of the emitter region 12 vary. Therefore, such measures may be taken that a portion having the inclination is treated as an inactive region, and the emitter region 12 is not formed, so that the portion is not made into the active portion 160. In the semiconductor device 100 of this example, since the polysilicon layer 151 is not provided, there is no need to set the inactive region, and the area of the active portion 160 can be increased.

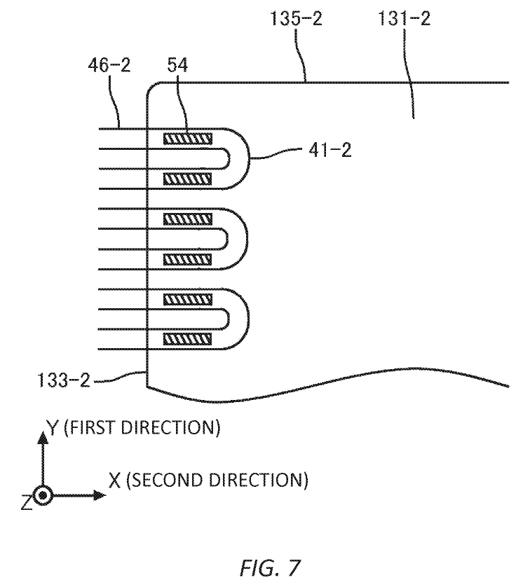

FIG. 7 is an enlarged top view of the region close to the second active gate runner 131-2 in FIG. 2A. In FIG. 7, the second connection portion 46-2 extends in the second direction and intersects the second end side 133-2. The second connection portion 46-2 extends to a portion overlapping the second active gate runner 131-2 and is connected to the second active gate runner 131-2 via the contact hole 54.

An end portion of the second connection portion 46-2 may be connected by the tip portion 41-2. As a result, electric field strength at the end portion of the second connection portion 46-2 can be reduced. The same may apply to the other connection portions 46.

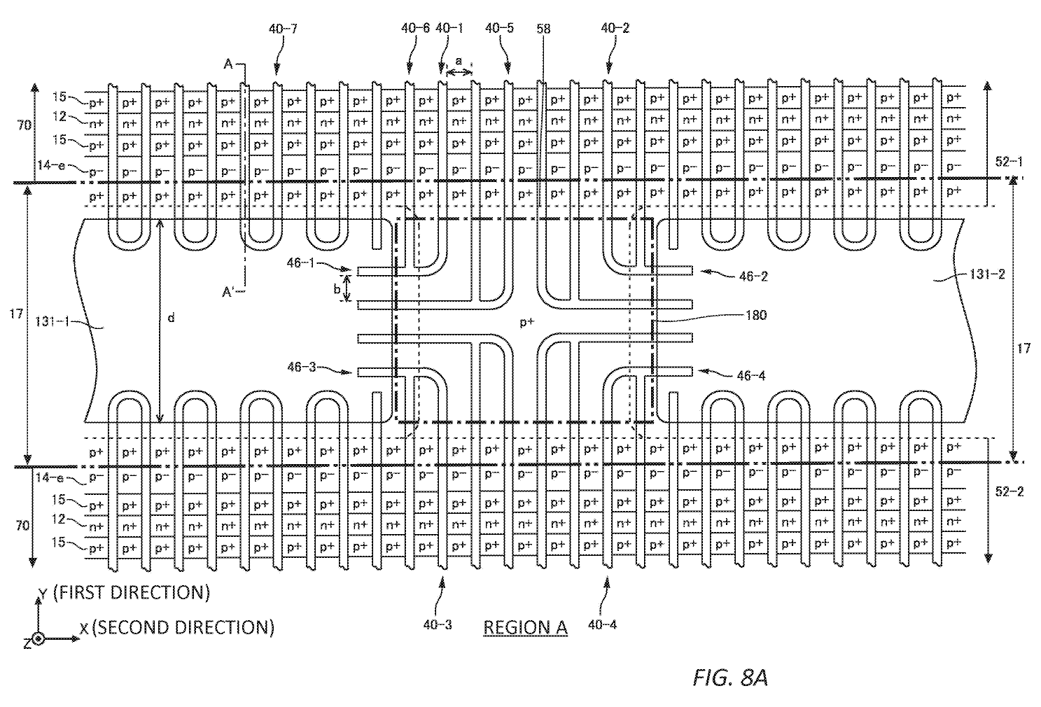

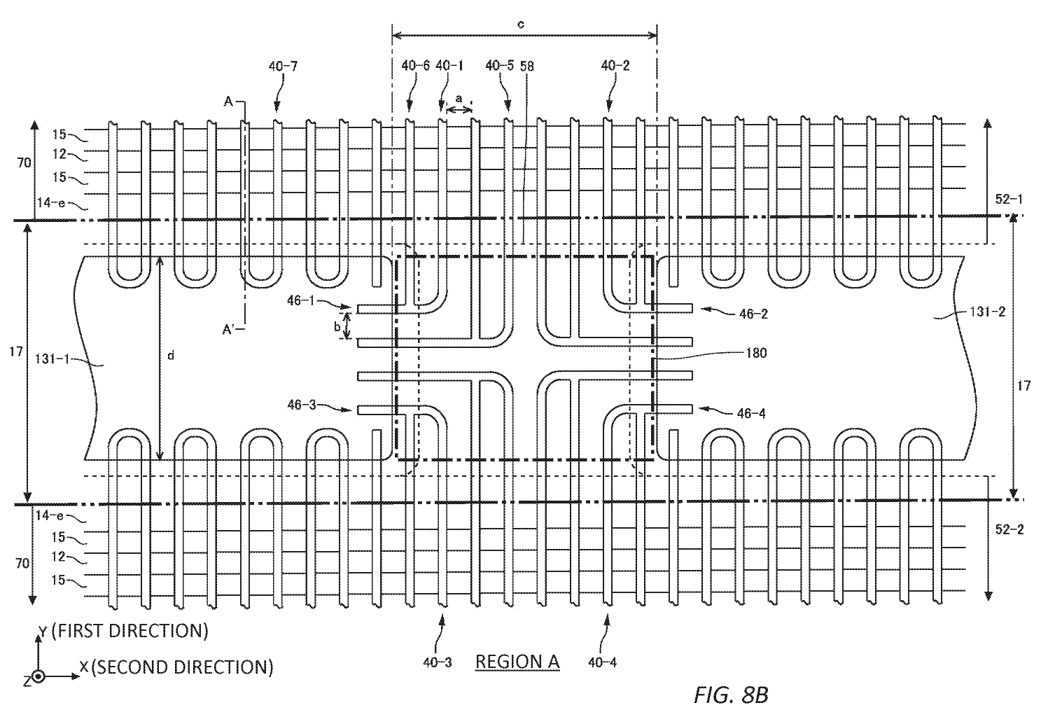

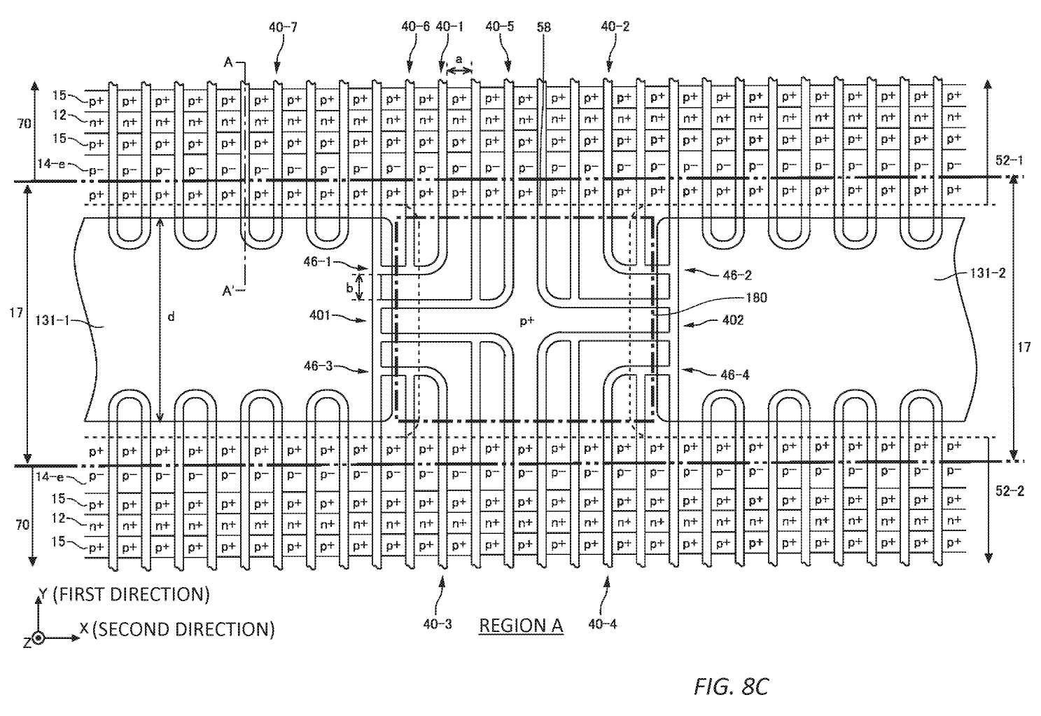

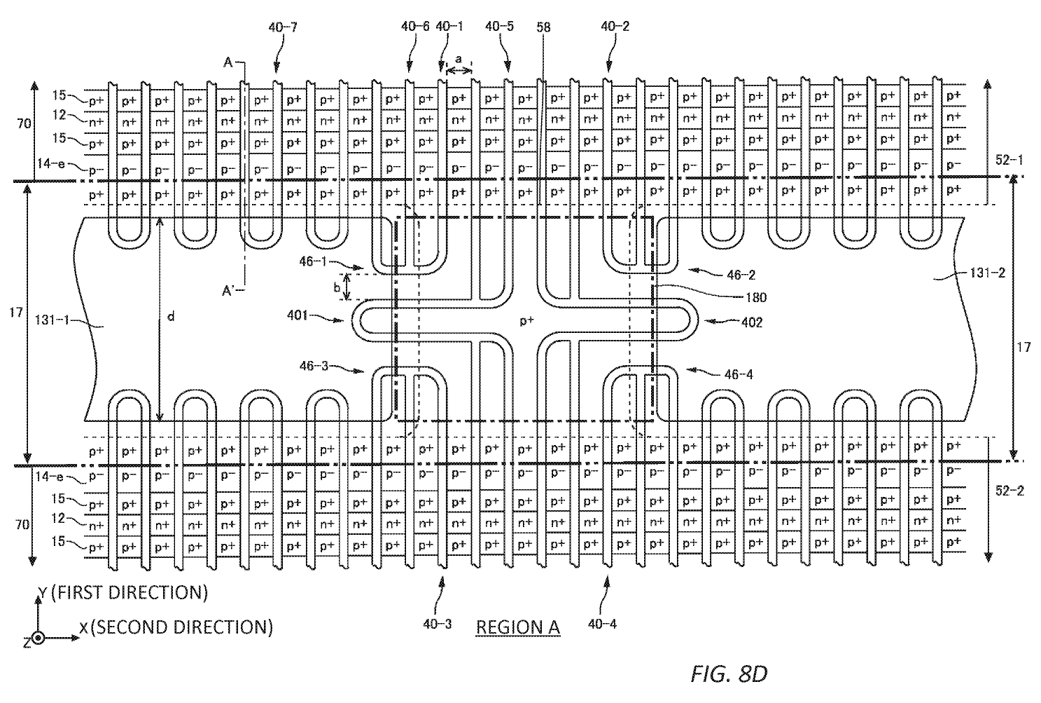

FIG. 8A is a top view of the region A in a modified example of the semiconductor device 100. FIG. 8A differs from the example of FIG. 2A in that the trench portion has the branch. The plurality of trench portions of this example include the sixth gate trench portion 40-6. The sixth gate trench portion 40-6 is connected to the first connection portion 46-1. In other words, the sixth gate trench portion 40-6 branches from the first connection portion 46-1. As a result, a total number of the connection portions 46 connected to the first active gate runner 131-1 decreases, and thus the length d of the first active gate runner 131-1 in the first direction can be reduced. The sixth gate trench portion 40-6 may branch from the first straight portion 47-1 of the first connection portion 46-1.

A trench portion corresponding to the sixth gate trench portion 40-6 may be connected to another connection portion 46. In other words, the trench portion corresponding to the sixth gate trench portion 40-6 may branch from another connection portion 46. In this example, trench portions corresponding to the sixth gate trench portion 40-6 branch from all of the connection portions 46 from the second connection portion 46-2 to the fourth connection portion 46-4. This makes it possible to reduce the length d of the first active gate runner 131-1 or the second active gate runner 131-2 in the first direction. In the example of FIG. 8A as well, the arrangement of the contact hole 54 may be similar to FIG. 2C.

FIG. 8B is a diagram for explaining the length c. FIG. 8B is the top view of the same range as FIG. 8A. However, indications such as n+ and p+ are omitted, and the length c is illustrated. The length of the spaced region 180 in the second direction is defined as the length c. The length of the first active gate runner 131-1 in the first direction is defined as the length d. A number of sixth gate trench portions 40-6 connected to one first connection portion 46-1 is defined as the number n. In this example, the number n is 1. These and the above-described interval a and interval b may satisfy the following relationship:
2 × (c/a) × (n + 1) ≥ d/b.

The above relationship expresses the relationship between a number of extending portions extending into the spaced region 180 (c/a) and a number of connection portions 46 connected to the first active gate runner 131-1 (d/b). The number n may be 0, may be 2, may be 3, or may be 4 or more.

FIG. 8C is a diagram for explaining another example of the trench portion in the example of FIG. 8A. FIG. 8C differs from FIG. 8A in that the semiconductor device 100 has the trench connection portion 401 and the trench connection portion 402. The trench connection portion 401 in this example is an example of the first trench connection portion, the third trench connection portion, and the fourth trench connection portion. The trench connection portion 401 in this example connects each of the plurality of first connection portions 46-1 and the plurality of third connection portions 46-3 which are connected to the first active gate runner 131-1. From each first connection portion 46-1, the sixth gate trench portion 40-6 branches, and from each third connection portion 46-3, the trench portion corresponding to the sixth gate trench portion 40-6 branches.

The trench connection portion 402 in this example is an example of the second trench connection portion, the fifth trench connection portion, and the sixth trench connection portion. The trench connection portion 402 in this example connects each of the plurality of second connection portions 46-2 and the plurality of fourth connection portions 46-4 which are connected to the second active gate runner 131-2. From each second connection portion 46-2 and each fourth connection portion 46-4, the trench portion corresponding to the sixth gate trench portion 40-6 branches.

The trench connection portion 401 and the trench connection portion 402 may be the gate trench portions 40. By connecting the end portions of the plurality of gate trench portions 40 with the trench connection portion 401 and the trench connection portion 402, respectively, isolated end portions of the gate trench portion 40 are eliminated. This makes it possible to suppress formation defects of the gate oxide film of the trench portion having an end portion as a single piece, and to suppress a decrease in the withstand voltage of the gate oxide film. The trench connection portion 401 and the trench connection portion 402 may be connected to the seventh gate trench portion 40-7.

FIG. 8D is a diagram illustrating another example of the trench portion in the example of FIG. 8A. In FIG. 8D, the shapes of the trench connection portion 401 and the trench connection portion 402 differ from those in FIG. 8C. The trench connection portion 401 of this example is an example of the fourth trench connection portion. In FIG. 8D, the trench connection portion 401 connects the first connection portion 46-1 (the connection portion of the fifth gate trench portion 40-5) and the third connection portion 46-3 (the connection portion of the gate trench portion 40 located second from the third gate trench portion 40-3 shown in FIG. 8D toward the positive side of the X axis) which are connected to the first active gate runner 131-1.

The trench connection portion 402 of this example is an example of the sixth trench connection portion. In FIG. 8D, the trench connection portion 402 connects a second connection portion 46-2 (the connection portion of the gate trench portion 40 located second from the second gate trench portion 40-2 shown in FIG. 8D toward the negative side of the X axis) and a fourth connection portion 46-4 (the connection portion of the gate trench portion 40 located second from the fourth gate trench portion 40-4 shown in FIG. 8D toward the negative side of the X axis) which are connected to the second active gate runner 131-2. The trench connection portion 401 and the trench connection portion 402 of this example are also arc-shaped.

The trench connection portion 401 and the trench connection portion 402 may be the gate trench portions 40. By connecting the ends of the plurality of gate trench portions 40 with the trench connection portion 401 and the trench connection portion 402, isolated ends of the gate trench portion 40 are eliminated. By further making the trench connection portion arc-shaped, mechanical and electrical stress on the gate oxide film can be further reduced. This makes it possible to suppress formation defects in the gate oxide film of the trench portion having an end as a single piece, and to suppress a decrease in the withstand voltage of the gate oxide film. Note that the first connection portion 46-1 may be connected to the seventh gate trench portion 40-7 below the first active gate runner 131-1. The same applies to the third connection portion 46-3. Also, the second connection portion 46-2 may be connected to the seventh gate trench portion 40-7 below the second active gate runner 131-2. The same applies to the fourth connection portion 46-4.

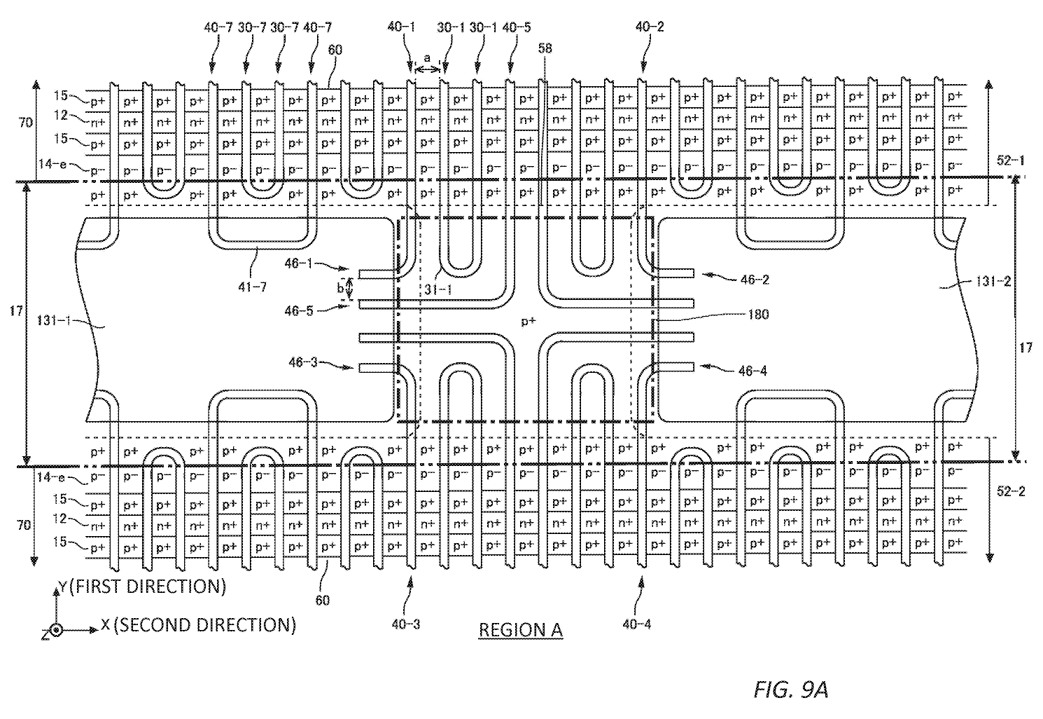

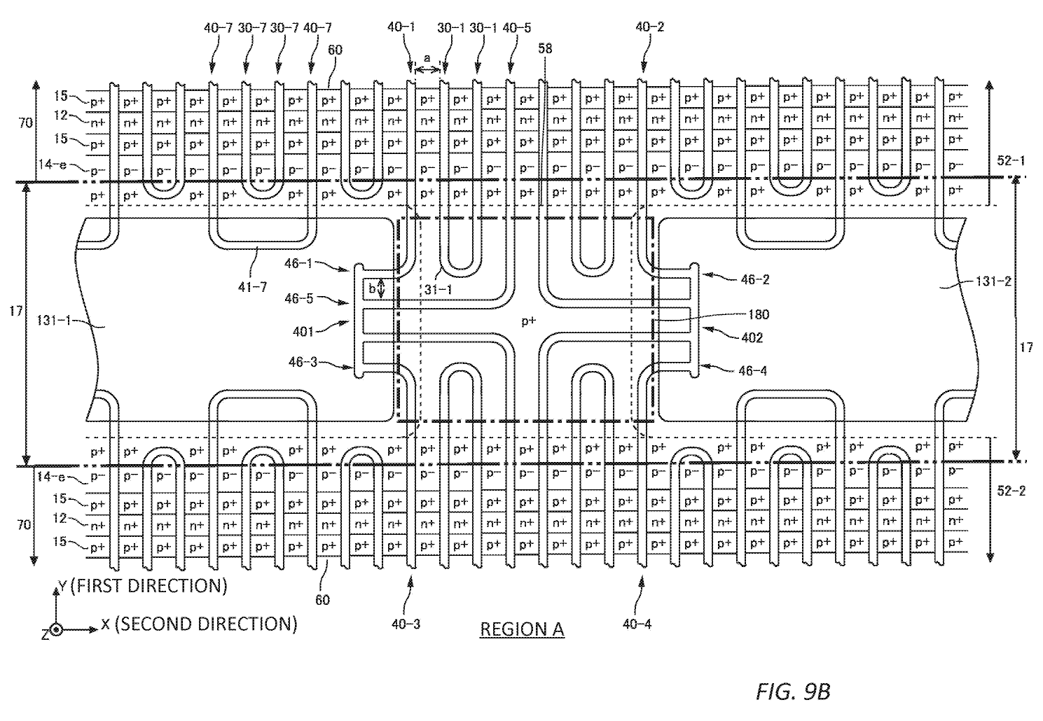

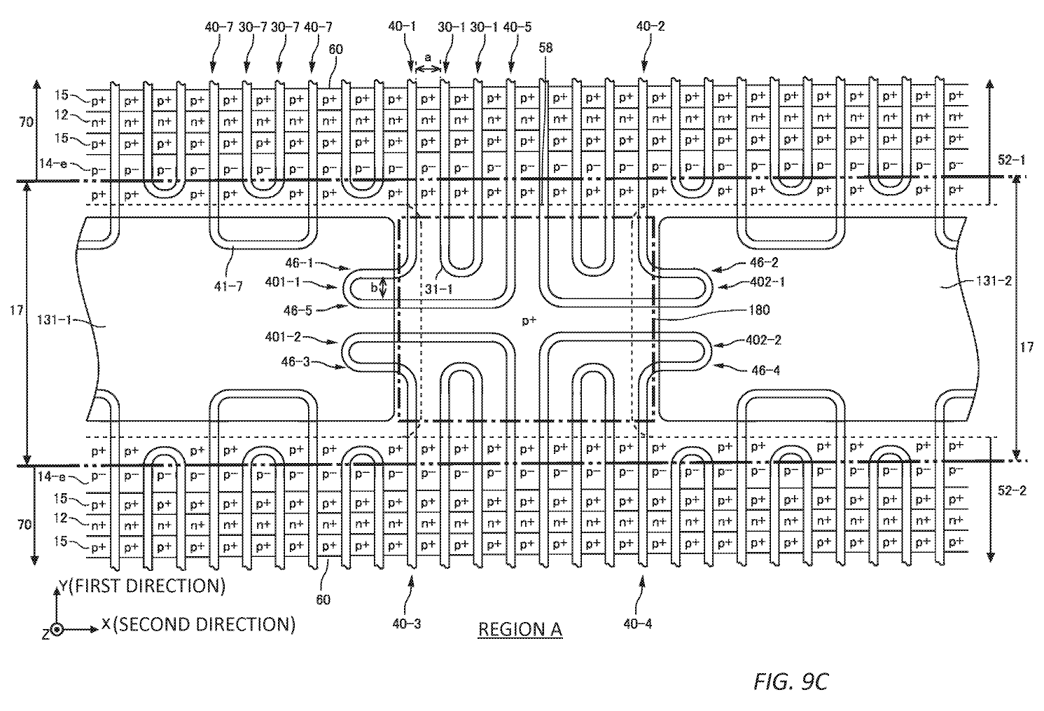

FIG. 9A is a top view of the region A in a modified example of the semiconductor device 100. In the semiconductor device 100 of this example, the plurality of trench portions differs from the example of FIG. 2A in that the plurality of trench portions has the dummy trench portion 30. The dummy trench portion 30 may have a configuration including, like the gate trench portion 40, the trench provided in the semiconductor substrate 10, the dielectric film provided on an inner wall of the trench, and the conductive portion insulated from the semiconductor substrate 10 by the dielectric film. However, the conductive portion of the dummy trench portion 30 is not connected to the active gate runner 131 and is connected to the emitter electrode 52.

In FIG. 9A, the dummy trench portion 30 facing the first active gate runner 131-1 in the first direction is shown as the seventh dummy trench portion 30-7. In FIG. 9A, two seventh dummy trench portions 30-7 are provided in the region surrounded by the two seventh gate trench portions 40-7 and the tip portion 41-7. The dummy trench portion 30-7 does not extend to a region overlapping the first active gate runner 131-1.

The plurality of trench portions may have a first dummy trench portion 30-1 provided between the first gate trench portion 40-1 and the fifth gate trench portion 40-5. The first dummy trench portion 30-1 of this example extends in the first direction to the spaced region 180. When the first dummy trench portion 30-1 extends to the spaced region 180, the interval between the trench portions in the spaced region 180 can be set to be equal to or less than the interval a. As a result, for example, even when the well region 17 is not provided in the spaced region 180, breakdown voltage can be secured.

The first dummy trench portion 30-1 may be provided between the two first gate trench portions 40-1. The two first dummy trench portions 30-1 may be connected by the tip portion 31-1. Also, in FIG. 9A, the dummy trench portion 30 extending to the spaced region 180 is provided beside the second gate trench portion 40-2. The same applies to the third gate trench portion 40-3 and the fourth gate trench portion 40-4. The modified example illustrated in FIG. 9A may be combined with the modified example illustrated in FIG. 8A. For example, the first dummy trench portion 30-1 may be provided between the two sixth gate trench portions 40-6. In the example of FIG. 9A as well, the arrangement of the contact hole 54 may be the same as in FIG. 2C.

FIG. 9B is a diagram illustrating another example of the trench portion in the example of FIG. 9A. FIG. 9B differs from FIG. 9A in that the semiconductor device 100 has the trench connection portion 401 and the trench connection portion 402. The trench connection portion 401 of this example is an example of the first trench connection portion, the third trench connection portion, and the fourth trench connection portion. The trench connection portion 401 of this example connects each of the plurality of first connection portions 46-1 and the plurality of third connection portions 46-3 which are connected to the first active gate runner 131-1. The trench connection portion 402 of this example is an example of the second trench connection portion, the fifth trench connection portion, and the sixth trench connection portion. The trench connection portion 402 of this example connects each of the plurality of second connection portions 46-2 and the plurality of fourth connection portions 46-4 which are connected to the second active gate runner 131-2.

The trench connection portion 401 and the trench connection portion 402 may be the gate trench portions 40. By connecting the end portions of the plurality of gate trench portions 40 respectively with the trench connection portion 401 and the trench connection portion 402, isolated end portions of the gate trench portion 40 are eliminated. Thereby, it is possible to suppress formation defects of the gate oxide film in a trench portion having an end portion as a single piece, and to suppress a decrease in the withstand voltage of the gate oxide film.

FIG. 9C is a diagram illustrating another example of the trench portion in the example of FIG. 9A. FIG. 9C differs from FIG. 9B in the shapes of the trench connection portion 401 and the trench connection portion 402. The semiconductor device 100 of this example includes the plurality of trench connection portions 401 (the trench connection portion 401-1 and the trench connection portion 401-2) and the plurality of trench connection portions 402 (the trench connection portion 402-1 and the trench connection portion 402-2). The trench connection portion 401-1 of this example is an example of the first trench connection portion. The trench connection portion 401-1 of this example connects the two adjacent first connection portions 46-1 connected to the first active gate runner 131-1 to each other. The trench connection portion 401-2 of this example is an example of the third trench connection portion. The trench connection portion 401-2 of this example connects the two adjacent third connection portions 46-3 connected to the first active gate runner 131-1 to each other. Each trench connection portion 401 in this example is arc-shaped.

The trench connection portion 402-1 in this example is an example of the second trench connection portion. The trench connection portion 402-1 in this example connects the two adjacent second connection portions 46-2 connected to the second active gate runner 131-2 to each other. The trench connection portion 402-2 in this example is an example of the fifth trench connection portion. The trench connection portion 402-2 in this example connects the two adjacent fourth connection portions 46-4 connected to the second active gate runner 131-2 to each other. Each trench connection portion 402 in this example is arc-shaped.

The trench connection portion 401 and the trench connection portion 402 may be the gate trench portions 40. By respectively connecting the end portions of the plurality of gate trench portions 40 with the trench connection portion 401 and the trench connection portion 402, isolated end portions of the gate trench portion 40 are eliminated. By further making the trench connection portion arc-shaped, mechanical and electrical stress on the gate oxide film can be further reduced. As a result, formation defects in the gate oxide film of the trench portion having an end portion in one line can be suppressed, and a decrease in the withstand voltage of the gate oxide film can be suppressed.

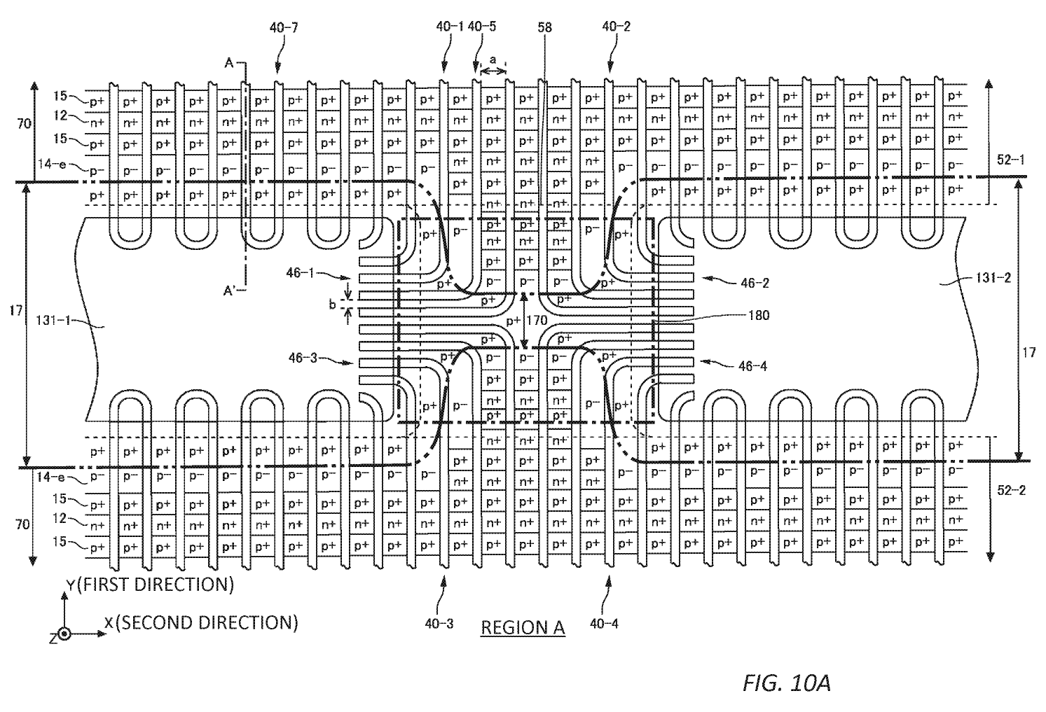

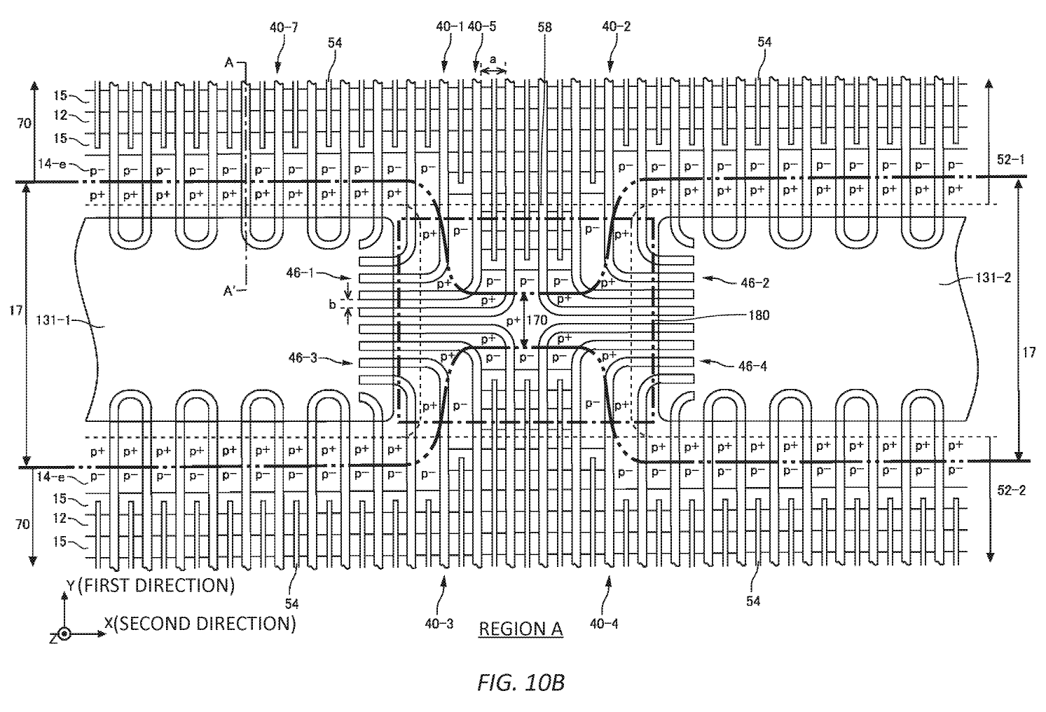

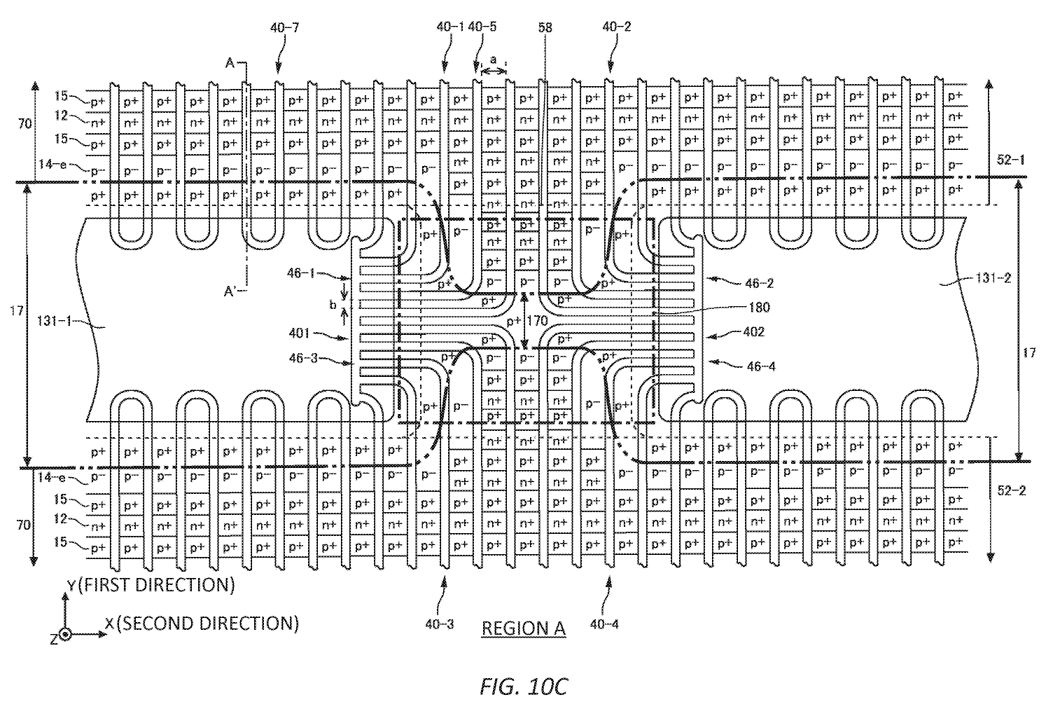

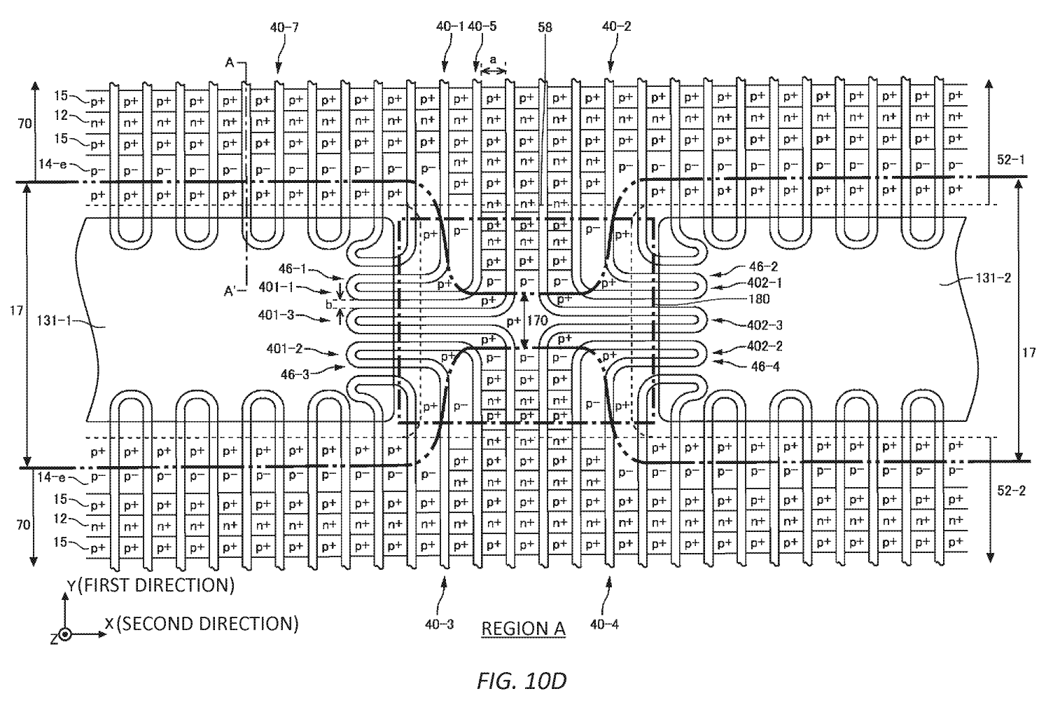

FIG. 10A is a top view of the region A in the modified example of the semiconductor device 100. The emitter region 12 in this example is also provided in the spaced region 180 and differs from FIG. 2A in that the well region 17 has a constricted portion 170 in the spaced region 180. The emitter region 12 in this example is in contact with the extending portion 49-1 of the first gate trench portion 40-1 in the spaced region 180. The portion in which the emitter region 12 is provided in the spaced region 180 may also be included in the transistor portion 70. The width of the well region 17 in the first direction (Y axis direction) in the spaced region 180 is smaller than one or both of the width of the first active gate runner 131-1 in the first direction (Y axis direction) or the width of the second active gate runner 131-2 in the first direction (Y axis direction). A number of arrays of the emitter region 12 arranged along the trench portion connected to the constricted portion 170 of the well region 17 is greater than a number of arrays of the emitter region 12 arranged along the trench portion connected to the non-constricted well region 17. This makes it possible to increase the channel density and increase the area of the active portion 160.

The emitter region 12 need not be in contact with the connection portion 46-1 in the spaced region 180. The same applies to each trench portion from the second gate trench portion 40-2 to the fifth gate trench portion 40-5. The modified example shown in FIG. 10A may be combined with the modified example shown in FIG. 8A or FIG. 9A.

FIG. 10B is a diagram illustrating an example of the arrangement of the contact hole 54 in the example of FIG. 10A. The contact hole 54 may be provided in the spaced region 180. In FIG. 10B, the contact hole 54 provided in the mesa portion 60 facing the spaced region 180 in the first direction extends to the spaced region 180. An end portion of the contact hole 54 is located above the contact region 15 in contact with the base region 14-e in the first direction. The bridge electrode portion 58 electrically connects to the emitter region 12 or the contact region 15 via the contact hole 54.

FIG. 10C is a diagram illustrating another example of the trench portion in the example of FIG. 10A. The trench connection portion 401 of this example is an example of the first trench connection portion, the third trench connection portion, and the fourth trench connection portion. The trench connection portion 401 of this example connects each of the plurality of first connection portions 46-1 and the plurality of third connection portions 46-3 which are connected to the first active gate runner 131-1. The trench connection portion 402 of this example is an example of the second trench connection portion, the fifth trench connection portion, and the sixth trench connection portion. The trench connection portion 402 of this example connects each of the plurality of second connection portions 46-2 and the plurality of fourth connection portions 46-4 which are connected to the second active gate runner 131-2.

The trench connection portion 401 and the trench connection portion 402 may be the gate trench portions 40. By connecting the ends of the plurality of gate trench portions 40 respectively with the trench connection portion 401 and the trench connection portion 402, isolated ends of the gate trench portion 40 are eliminated. As a result, it is possible to suppress formation defects of the gate oxide film of the trench portion having an end as a single piece, and to suppress a decrease in the withstand voltage of the gate oxide film. The trench connection portion 401 and the trench connection portion 402 may be connected to the seventh gate trench portion 40. The end portion of the trench connection portion 401 in the Y axis direction and the gate trench portion 40 that is not connected to the trench connection portion 401 around the trench connection portion 401 may be separated from each other. The trench connection portion 401 and the gate trench portion 40 around the trench connection portion 401 may be separated by a width in the array direction of the gate trench portion 40 or more. The same applies to other examples.

FIG. 10D is a diagram illustrating another example of the trench portion in the example of FIG. 10A. In FIG. 10D, the shapes of the trench connection portion 401 and the trench connection portion 402 are different from those in FIG. 2D. The semiconductor device 100 of this example includes the plurality of trench connection portions 401 (the trench connection portion 401-1, the trench connection portion 401-2, and the trench connection portion 401-3) and the plurality of trench connection portions 402 (the trench connection portion 402-1, the trench connection portion 402-2, and the trench connection portion 402-3). The trench connection portion 401-1 of this example is an example of the first trench connection portion. In FIG. 10D, the trench connection portion 401-1 connects the two adjacent first connection portions 46-1 among the plurality of first connection portions 46-1 connected to the first active gate runner 131-1 to each other. The trench connection portion 401-2 of this example is an example of the third trench connection portion. In FIG. 10D, the trench connection portion 401-2 connects the two adjacent third connection portions 46-3 among the plurality of third connection portions 46-3 connected to the first active gate runner 131-1 to each other. The trench connection portion 401-3 of this example is an example of the fourth trench connection portion. In FIG. 10D, the trench connection portion 401-3 connects the first connection portion 46-1 and the third connection portion 46-3 which are connected to the first active gate runner 131-1. Each trench connection portion 401 of this example is arc-shaped.

The trench connection portion 402-1 of this example is an example of the second trench connection portion. In FIG. 10D, the trench connection portion 402-1 connects the two adjacent second connection portions 46-2 among the plurality of second connection portions 46-2 connected to the second active gate runner 131-2 to each other. The trench connection portion 402-2 of this example is an example of the fifth trench connection portion. In FIG. 10D, the trench connection portion 402-2 connects the two adjacent fourth connection portions 46-4 among the plurality of fourth connection portions 46-4 connected to the second active gate runner 131-2. The trench connection portion 402-3 of this example is an example of the sixth trench connection portion. In FIG. 10D, the trench connection portion 402-3 connects the second connection portion 46-2 and the fourth connection portion 46-4 which are connected to the second active gate runner 131-2. Each trench connection portion 402 of this example is arc-shaped.

The trench connection portion 401 and the trench connection portion 402 may be the gate trench portions 40. By connecting the ends of the plurality of gate trench portions 40 by the trench connection portion 401 and the trench connection portion 402, isolated ends of the gate trench portion 40 are eliminated. Furthermore, by making the trench connection portion arc-shaped, mechanical and electrical stress on the gate oxide film can be further reduced. As a result, formation defects in the gate oxide film of the trench portion having an end in one line can be suppressed, and a decrease in the withstand voltage of the gate oxide film can be suppressed.

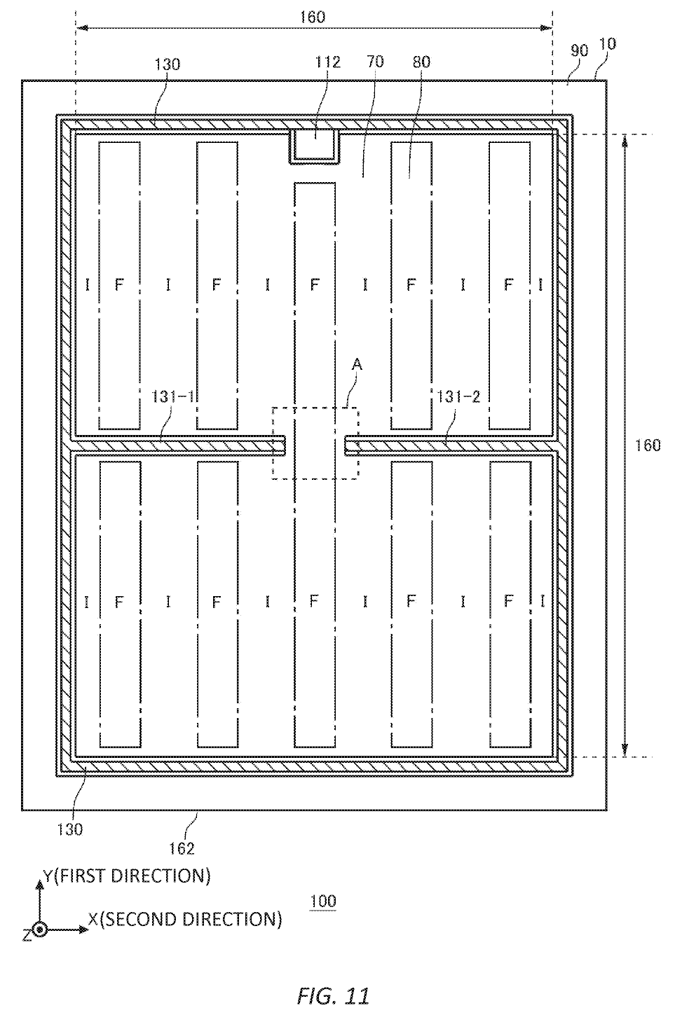

FIG. 11 is an overall top view of a modified example of the semiconductor device 100. The semiconductor device 100 of this example has the transistor portion 70 and the diode portion 80. The transistor portion 70 and the diode portion 80 of this example extend in a first direction and are alternately arranged in a second direction. In FIG. 11, the transistor portion 70 is denoted by I, and the diode portion 80 is denoted by F.

At least a part of the transistor portion 70 may face the spaced region 180 in the first direction. At least a part of the diode portion 80 may face the spaced region 180 in the first direction. In the first direction, the diode portion 80 provided with the spaced region 180 interposed therebetween may be continuous through the spaced region 180. In the first direction, the diode portion 80 provided with the active gate runner 131 interposed therebetween is separated by the active gate runner 131.

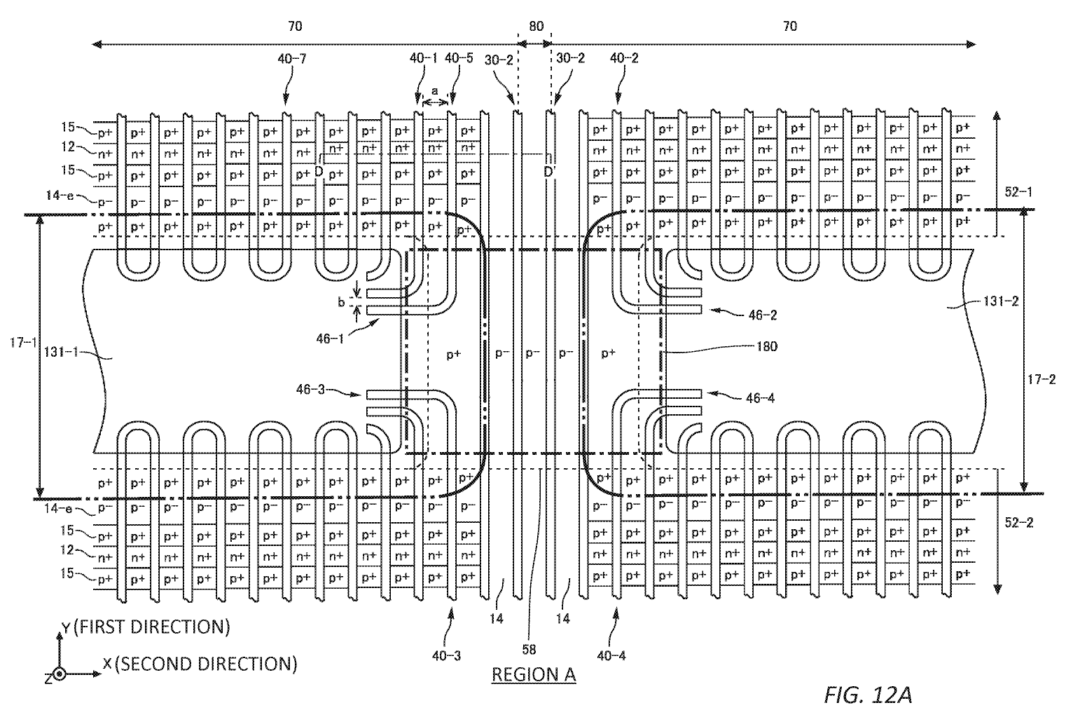

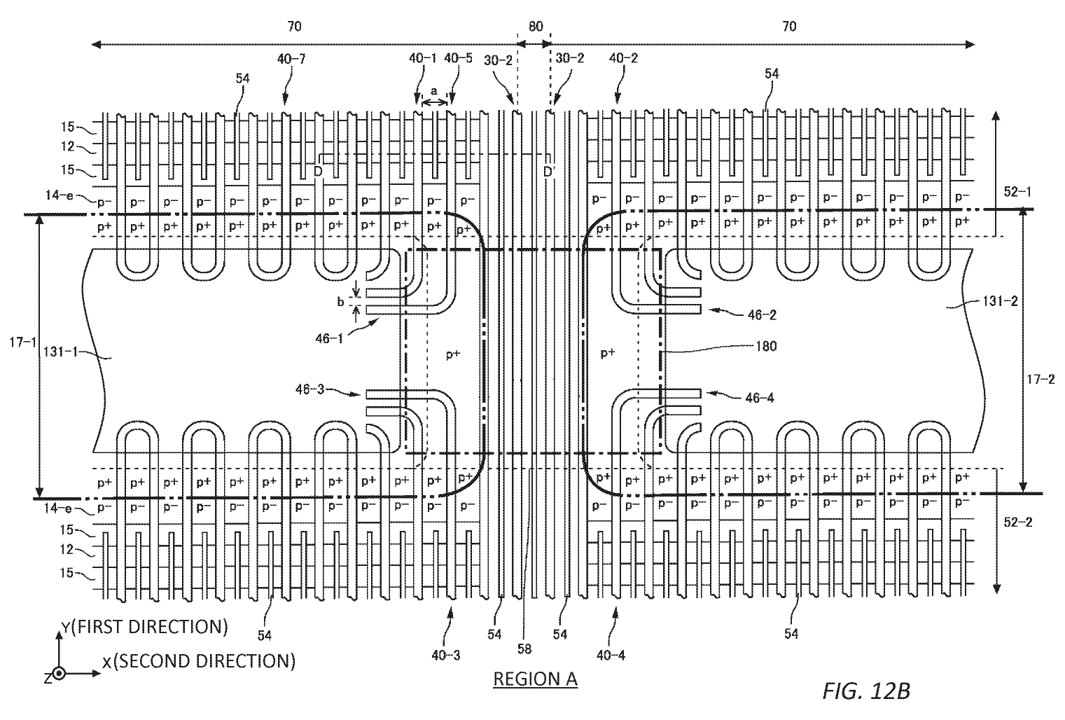

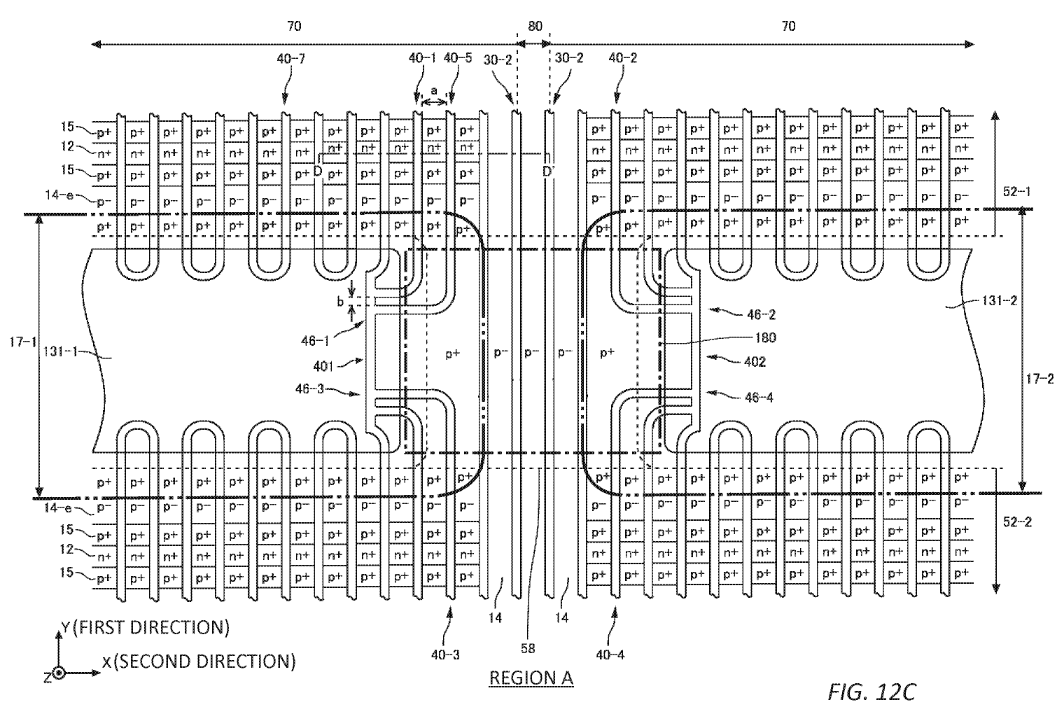

FIG. 12A illustrates an enlarged view of the region A in FIG. 11. This example differs from the example of FIG. 2A in that, in the spaced region 180, the transistor portion 70 is provided in the region close to the first end side 133-1 and the second end side 133-2. Also, this example differs from the example of FIG. 2A in that, in the spaced region 180, the diode portion 80 is provided between the transistor portions 70 in the second direction. The diode portion 80 may be a region obtained by projecting, onto the upper surface, the cathode region provided on the lower surface of the semiconductor substrate 10 described later. With such an arrangement, the cathode region and the well region 17 below the active gate runner 131 can be separated, and reverse recovery withstand capability can be increased. The diode portion 80 of this example is provided at the center of the spaced region 180. In the spaced region 180, a portion where the emitter region 12 is provided may be the transistor portion 70.

In the diode portion 80, the plurality of trench portions may include the second dummy trench portion 30-2 provided from below the first emitter electrode 52-1 to below the second emitter electrode 52-2. That is, the second dummy trench portion 30-2 penetrates the spaced region 180. The well region 17 is not formed in the central portion of the spaced region 180. The well region 17 has the well region 17-1 in the first active gate runner 131-1 and the well region 17-2 in the second active gate runner 131-2, and the well region 17-1 and the well region 17-2 are spaced apart. Meanwhile, both the well region 17-1 and the well region 17-2 are connected to the annular well region 17 formed in the outer peripheral portion.

FIG. 12B is a diagram illustrating an example of the arrangement of the contact hole 54 in the example of FIG. 12A. The contact hole 54 of the diode portion 80 may be formed in the spaced region 180. As a result, since the diode portion 80 formed in the spaced region 180 operates, the area of the diode portion 80 can be increased. The contact hole 54 need not be provided above the well region 17 in the spaced region 180. The contact hole 54 of this example is provided from below the first emitter electrode 52-1 to below the second emitter electrode 52-2. That is, the contact hole 54 of this example penetrates the spaced region 180. The bridge electrode portion 58 electrically connects to the anode region (base region 14) via the contact hole 54.

FIG. 12C is a diagram for explaining another example of the trench portion in the example of FIG. 12A. FIG. 12C differs from FIG. 12A in that the semiconductor device 100 has the trench connection portion 401 and the trench connection portion 402. The trench connection portion 401 of this example is an example of the first trench connection portion, the third trench connection portion, and the fourth trench connection portion. The trench connection portion 401 of this example connects each of the plurality of first connection portions 46-1 and the plurality of third connection portions 46-3 which are connected to the first active gate runner 131-1. The trench connection portion 402 of this example is an example of the second trench connection portion, the fifth trench connection portion, and the sixth trench connection portion. The trench connection portion 402 of this example connects each of the plurality of second connection portions 46-2 and the plurality of fourth connection portions 46-4 which are connected to the second active gate runner 131-2.

The trench connection portion 401 and the trench connection portion 402 may be the gate trench portions 40. By respectively connecting the ends of the plurality of gate trench portions 40 with the trench connection portion 401 and the trench connection portion 402, isolated ends of the gate trench portion 40 are eliminated. As a result, it is possible to suppress formation defects of the gate oxide film of the trench portion having an end as a single piece, and to suppress a decrease in the withstand voltage of the gate oxide film. The trench connection portion 401 and the trench connection portion 402 may be connected to the seventh gate trench portion 40.

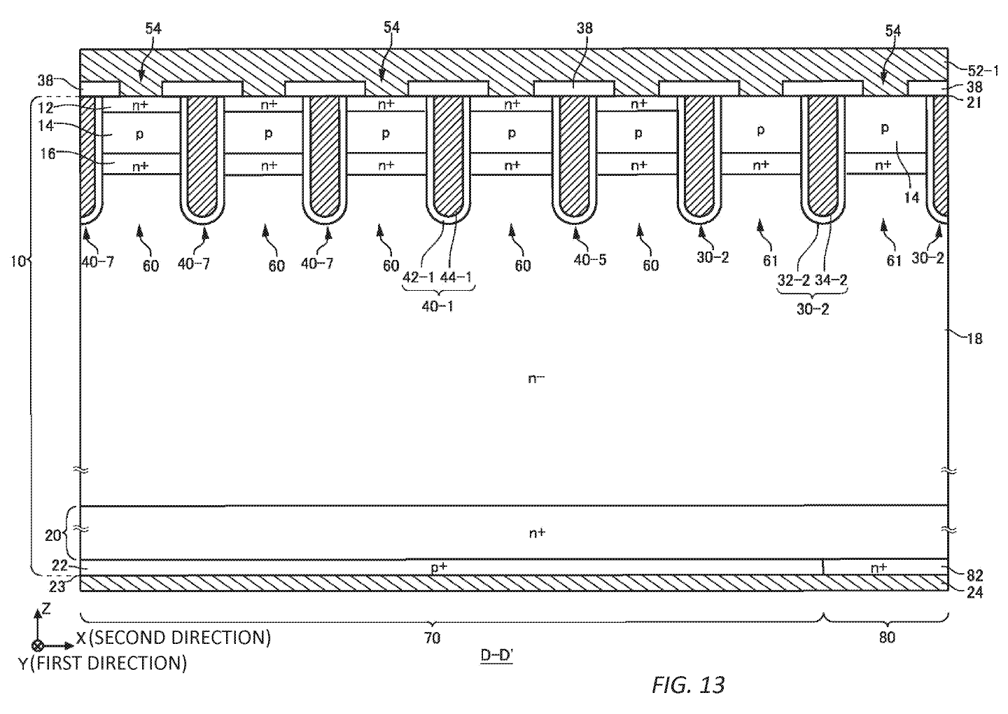

FIG. 13 is a diagram illustrating an example of the cross-section D-D' in FIG. 12A. The cross-section D-D' is the XZ plane passing through the emitter region 12 of the transistor portion 70 and the base region 14 of the diode portion 80. The semiconductor device 100 of this example has, in the cross section, the semiconductor substrate 10, the interlayer dielectric film 38, the first emitter electrode 52-1, and the collector electrode 24.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The contact hole 54 is provided in the interlayer dielectric film 38.

The first emitter electrode 52-1 is provided above the interlayer dielectric film 38. The first emitter electrode 52-1 is in contact with the upper surface 21 of the semiconductor substrate 10 through the contact hole 54 of the interlayer dielectric film 38. The collector electrode 24 is provided on a lower surface 23 of the semiconductor substrate 10. The first emitter electrode 52-1 and the collector electrode 24 are formed of the metal material such as aluminum.

The semiconductor substrate 10 has an upper surface 21 and the lower surface 23. The semiconductor substrate 10 has the drift region 18 of the first conductivity type. The drift region 18 in this example is of n- type. The drift region 18 is provided in each of the transistor portion 70 and the diode portion 80.

In the mesa portion 60 of the transistor portion 70, the emitter region 12 of the first conductivity type and the base region 14 of the second conductivity type are provided in order from the upper surface 21 side of the semiconductor substrate 10. The emitter region 12 in this example is of n+ type, and the base region 14 is of p type. The drift region 18 is provided below the base region 14. The n+ type accumulation region 16 may be provided in the mesa portion 60. The accumulation region 16 is arranged between the base region 14 and the drift region 18.

The emitter region 12 is provided on the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of this example is provided in contact with the emitter region 12. The base region 14 may be in contact with the trench portions on both sides of the mesa portion 60.

The accumulation region 16 is provided below the base region 14. The accumulation region 16 is an n+ type region with a higher doping concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

In the mesa portion 61 of the diode portion 80, the p type base region 14 is provided in contact with the upper surface 21 of the semiconductor substrate 10. The base region 14 of the diode portion 80 functions as the anode region of the diode portion 80. The mesa portion 61 of the diode portion 80 is not provided with the emitter region 12. The drift region 18 is provided below the base region 14. In the mesa portion 61, the accumulation region 16 may be provided below the base region 14.

In each of the transistor portion 70 and the diode portion 80, the n+ type buffer region 20 may be provided below the drift region 18. The doping concentration of the buffer region 20 is higher than the doping concentration of the drift region 18. The buffer region 20 has a concentration peak having a higher doping concentration than the doping concentration of the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 may have two or more concentration peaks in the depth direction (Z axis direction) of the semiconductor substrate 10. The concentration peak of the buffer region 20 may be provided at the same depth position as, for example, a concentration peak of hydrogen (a proton) or phosphorous. The buffer region 20 may function as the field stop layer that prevents the depletion layer extending from the lower end of the base region 14 from reaching the collector region 22 and the cathode region 82.

In the transistor portion 70, the p+ type collector region 22 is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

In the diode portion 80, the n type cathode region 82 is provided below the buffer region 20. A donor concentration of the cathode region 82 is higher than a donor concentration of the drift region 18. A donor of the cathode region 82 is, for example, hydrogen or phosphorous. Note that an element serving as a donor and an acceptor in each region is not limited to the above-described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion extends from the upper surface 21 of the semiconductor substrate 10 through the base region 14 to below the base region 14. In a region in which at least any of the emitter region 12, the contact region 15, or the accumulation region 16 is provided, each trench portion also penetrates these doping regions. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The transistor portion 70 is provided with the gate trench portion 40. As described above, the transistor portion 70 may be provided with the dummy trench portion 30. In the diode portion 80, the dummy trench portion 30 is provided, and the gate trench portion 40 is not provided. In this example, at the boundary between the diode portion 80 and the transistor portion 70 in the X axis direction, the boundary between the cathode region 82 and the collector region 22 is disposed.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52 in another cross section. The dummy dielectric film 32 is provided covering an inner wall of the dummy trench. The dummy conductive portion 34 is provided in the dummy trench and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross section) convexly downward.

The cross section of the transistor portion 70 shown in FIG. 2A and the like may be the same as the cross section of the transistor portion 70 shown in FIG. 13. The modified examples shown in FIGS. 11-13 may be combined with any of the modified examples shown in FIGS. 8A, 9A, or 10A.

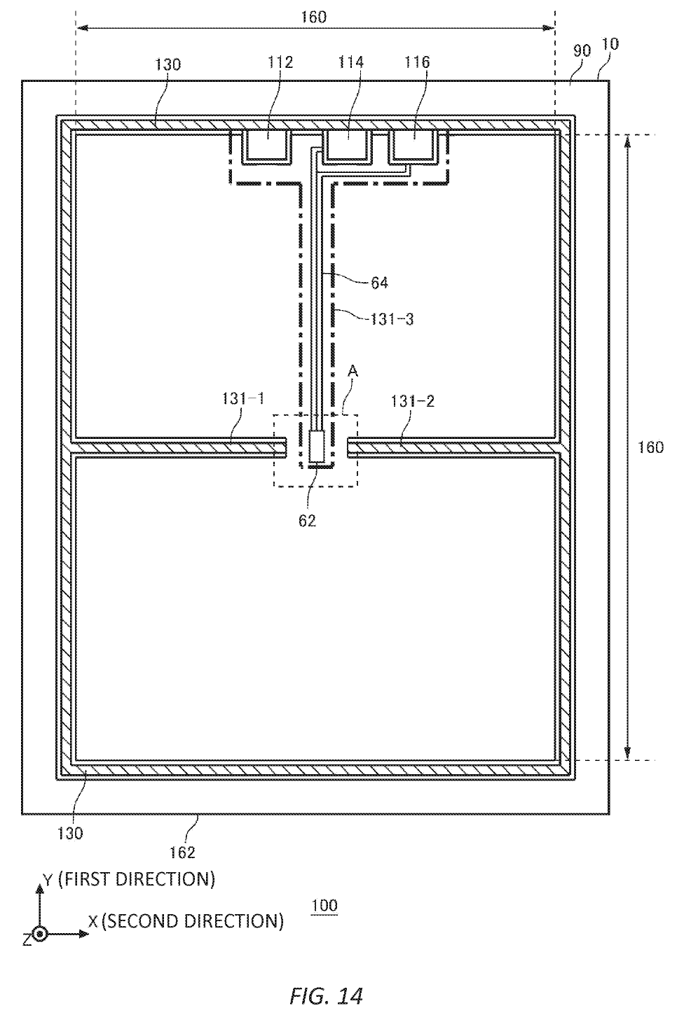

FIG. 14 is an overall top view of a modified example of the semiconductor device 100. The semiconductor device 100 of this example further includes the temperature sense portion 62, the temperature sense wiring 64, the anode pad 114, the cathode pad 116, and the third active gate runner 131-3.

The temperature sense portion 62 measures the temperature of the semiconductor device 100. The temperature sense portion 62 is, for example, the pn junction diode. The temperature sense portion 62 of this example is provided at least partly in the spaced region 180. The anode pad 114 and the cathode pad 116 are connected to the temperature sense portion 62 via the temperature sense wiring 64 and output a signal corresponding to a temperature to the outside.

The third active gate runner 131-3 is disposed along the temperature sense portion 62, the temperature sense wiring 64, the gate pad 112, the anode pad 114, and the cathode pad 116. The third active gate runner 131-3 is provided in the active portion 160 in the same manner as the other active gate runners 131 and transmits the gate voltage from the gate pad 112 to the gate trench portion 40. In FIG. 14, the third active gate runner 131-3 is indicated by a dashed-and-dotted line.

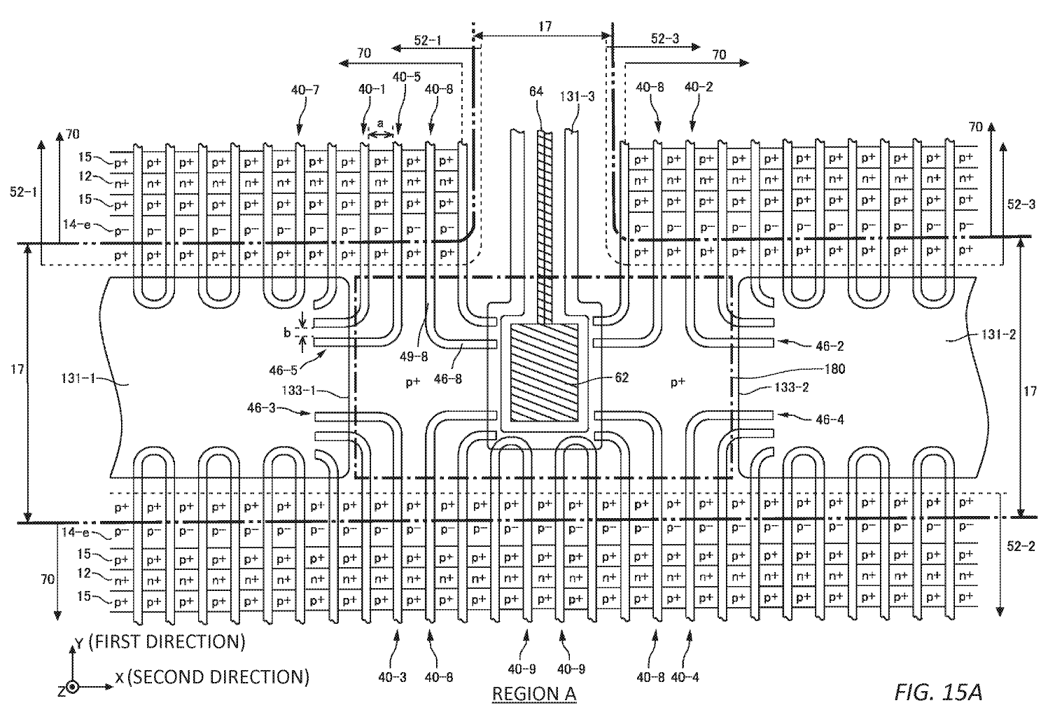

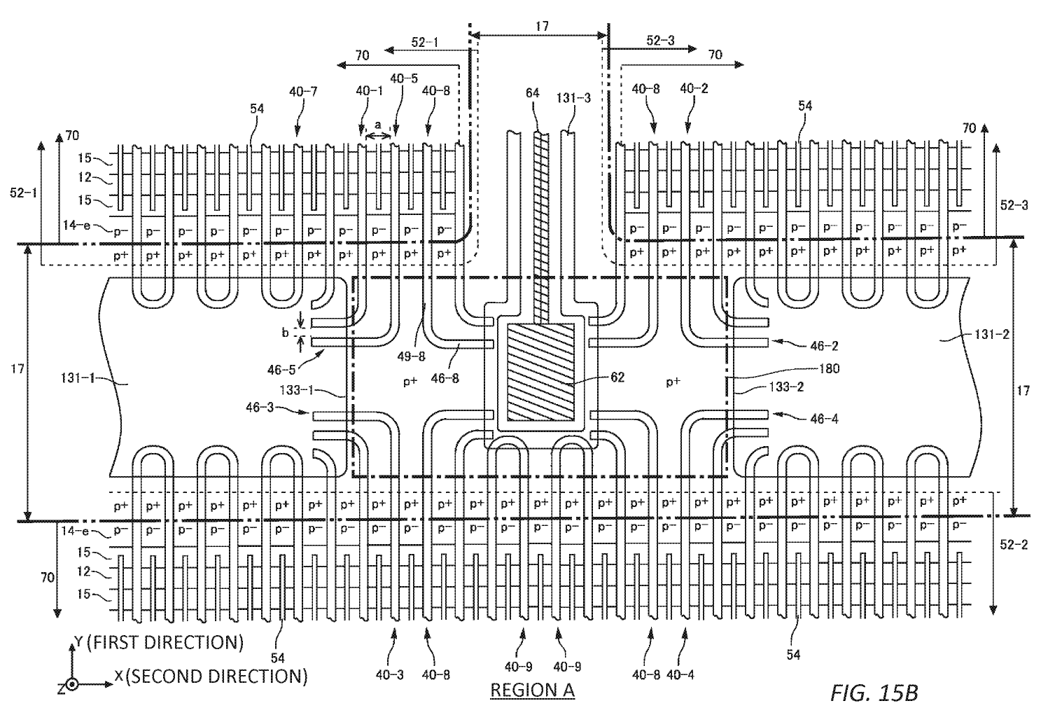

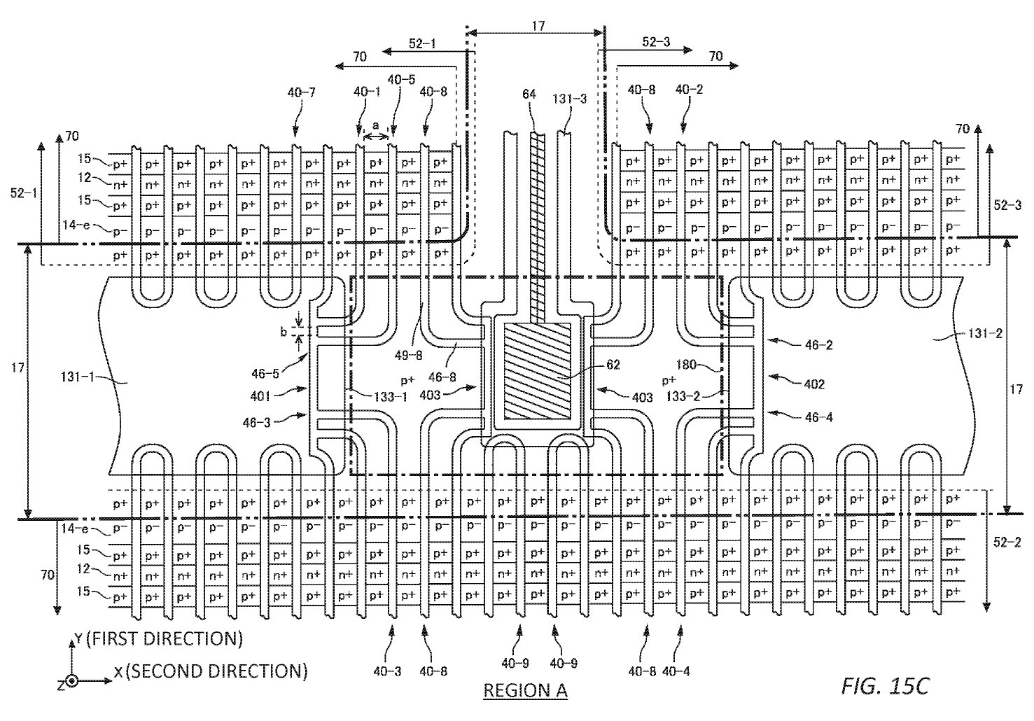

FIG. 15 illustrates an enlarged view of the region A in FIG. 14. In this example, the temperature sense portion 62 is provided at least partly in the spaced region. The semiconductor device 100 of this example includes the first emitter electrode 52-1, the second emitter electrode 52-2, and a third emitter electrode 52-3. The first emitter electrode 52-1 and the third emitter electrode 52-3 are provided so as to sandwich the temperature sense wiring 64 in the second direction.

The third active gate runner 131-3 is provided between the temperature sense portion 62 and the emitter electrode 52. In this example, the third active gate runner 131-3 is also provided between the first emitter electrode 52-1 and the third emitter electrode 52-3 and the temperature sense wiring 64. The temperature sense wiring 64 of this example extends in the first direction. The third active gate runner 131-3 of this example is also provided between the first active gate runner 131-1 and the second active gate runner 131-2 and the temperature sense portion 62.

The plurality of trench portions of this example have the eighth gate trench portion 40-8 connected to the third active gate runner 131-3. This makes it possible to suppress gate delay of the eighth gate trench portion 40-8. The eighth gate trench portion 40-8 may be connected to the third active gate runner 131-3 in the spaced region 180. The eighth gate trench portion 40-8 may be connected to the portion of the third active gate runner 131-3 facing the first end side 133-1 or the second end side 133-2 in the second direction. A plurality of eighth gate trench portions may also be provided.

The eighth gate trench portion 40-8 may have the eighth extending portion 49-8 extending in the first direction. The eighth extending portion 49-8 may extend to the spaced region 180 and may not extend to the spaced region 180. When at least a part of the temperature sense portion 62 is provided outside the spaced region 180, the eighth extending portion 49-8 need not extend to the spaced region 180.

The eighth gate trench portion 40-8 may have the eighth connection portion 46-8 that connects the eighth extending portion 49-8 to the third active gate runner 131-3. In this example, the eighth connection portion 46-8 is provided in the spaced region 180 and has the longitudinal direction in the second direction. However, when the eighth extending portion 49-8 does not extend to the spaced region, the eighth connection portion 46-8 may be disposed outside the spaced region 180. As in FIG. 4, the eighth connection portion 46-8 may also have a straight portion and a curved portion.

The eighth gate trench portion 40-8 may be provided between the first gate trench portion 40-1 and the temperature sense portion 62, may be provided between the second gate trench portion 40-2 and the temperature sense portion 62, may be provided between the third gate trench portion 40-3 and the temperature sense portion 62, may be provided between the fourth gate trench portion 40-4 and the temperature sense portion 62, and may be provided between the fifth gate trench portion 40-5 and the temperature sense portion 62. The eighth gate trench portion 40-8 may extend from below any emitter electrode 52 to the spaced region 180.

The plurality of trench portions in this example include the ninth gate trench portion 40-9 facing the temperature sense portion 62 in the first direction. The ninth gate trench portion 40-9 may be connected to the third active gate runner 131-3. This can suppress delay of the ninth gate trench portion 40-9. The ninth gate trench portion 40-9 may extend to the spaced region 180 and may not extend.

Also in the modified example shown in FIG. 15A, the bridge electrode portion 58 may be provided. In that case, the semiconductor device 100 may include the bridge electrode portion 58 connecting the first emitter electrode 52-1 and the second emitter electrode 52-2, and the bridge electrode portion 58 connecting the third emitter electrode 52-3 and the second emitter electrode 52-2.

FIG. 15B is a diagram illustrating an example of the arrangement of the contact hole 54 in the example of FIG. 15A. Also in this example, the contact hole 54 is provided above the emitter region 12 and the contact region 15 and is not provided above the base region 14 and the well region 17. An end portion of the contact hole 54 in the first direction is located above the contact region 15 that is in contact with the base region 14-e in the first direction. The contact hole 54 is also provided in the mesa portion 60 facing the spaced region 180 in the first direction, but the contact hole 54 of this example is not provided in the spaced region 180.

FIG. 15C is a diagram for explaining another example of the trench portion in the example of FIG. 15A. FIG. 15C differs from FIG. 15A in that the semiconductor device 100 has the trench connection portion 401, the trench connection portion 402, and the trench connection portion 403. The trench connection portion 401 in this example is an example of the first trench connection portion, the third trench connection portion, and the fourth trench connection portion. The trench connection portion 401 in this example connects each of the plurality of first connection portions 46-1 and the plurality of third connection portions 46-3 which are connected to the first active gate runner 131-1. The trench connection portion 402 of this example is an example of the second trench connection portion, the fifth trench connection portion, and the sixth trench connection portion. The trench connection portion 402 of this example connects each of the plurality of second connection portions 46-2 and the plurality of fourth connection portions 46-4 which are connected to the second active gate runner 131-2.

The semiconductor device 100 may have a seventh trench connection portion that connects the plurality of eighth connection portions 46-8 to each other. The plurality of eighth connection portions 46-8 may be the respective eighth connection portions 46-8 of eighth gate trench portions provided below different emitter electrodes 52 and may also be the respective eighth connection portions 46-8 in a case where the plurality of eighth gate trench portions 40-8 are provided below the same emitter electrode 52. In FIG. 15C, for example, the trench portion adjacent on the X axis positive side to the eighth gate trench portion 40-8 provided between the first gate trench portion 40-1 and the temperature sense portion 62 may also be regarded as the eighth gate trench portion 40-8.

The trench connection portion 403 of this example is an example of the seventh trench connection portion. The trench connection portion 403 of this example connects the plurality of eighth connection portions 46-8 connected to the third active gate runner 131-3 to each other. A plurality of trench connection portions 403 may be provided.

The trench connection portion 401, the trench connection portion 402, and the trench connection portion 403 may be the gate trench portions 40. By connecting the end portions of the plurality of gate trench portions 40 with the trench connection portion 401, the trench connection portion 402, and the trench connection portion 403, respectively, isolated end portions of the gate trench portion 40 are eliminated. Thereby, it is possible to suppress formation defects of the gate oxide film of the trench portion having an end portion as a single piece, and to suppress a decrease in the withstand voltage of the gate oxide film. The trench connection portion 401 and the trench connection portion 402 may be connected to the seventh gate trench portion 40.

While the embodiments of the present invention have been described, the technical scope of the invention is not limited to the above described embodiments. It is apparent to persons skilled in the art that various alterations or improvements can be added to the above-described embodiments. It is also apparent from the scope of the claims that the embodiments added with such alterations or improvements can be included in the technical scope of the invention.

This specification and the drawings also disclose inventions relating to the following items.

Supplementary Note 1
A semiconductor device including:
   a semiconductor substrate having an upper surface and a lower surface,
   a plurality of trench portions provided from the upper surface of the semiconductor substrate toward the inside and extending in a first direction on the upper surface,
   a first active gate runner extending in a second direction intersecting the first direction above the upper surface of the semiconductor substrate,
   a second active gate runner extending in the second direction and provided apart from the first active gate runner in the second direction, and
   a spaced region provided between the first active gate runner and the second active gate runner along the second direction,
   in which:
      the plurality of trench portions include a first gate trench portion, and the
      first gate trench portion has the first extending portion extending in the first direction to the spaced region, and
      a first connection portion provided in the spaced region and connecting the first extending portion to the first active gate runner.

Supplementary Note 2
The semiconductor device according to supplementary note 1,
in which in a top view,
   the first active gate runner has a first end side,
   the second active gate runner has a second end side facing the
   first end side in the second direction, and the first connection portion intersects the first end side.

Supplementary Note 3
The semiconductor device according to supplementary note 2, in which the first connection portion extends to a portion overlapping the first active gate runner.

Supplementary Note 4
The semiconductor device according to supplementary note 1, in which the first connection portion has a first straight portion extending in the second direction.

Supplementary Note 5
The semiconductor device according to supplementary note 4, in which the first connection portion has a first curved portion connecting the first straight portion and the first extending portion.

Supplementary Note 6
The semiconductor device according to supplementary note 1, in which the plurality of trench portions include a second gate trench portion, and
the second gate trench portion includes:
   a second extending portion extending in the first direction to the spaced region, and a second connection portion provided in the spaced region and connecting the second extending portion to the second active gate runner.

Supplementary Note 7
The semiconductor device according to supplementary note 6, including:
   a first emitter electrode provided above the upper surface of the semiconductor substrate, and
   a second emitter electrode disposed to face the first emitter electrode, sandwiching the first active gate runner, the second active gate runner, and the spaced region in the first direction,
   in which
      the first gate trench portion and the second gate trench portion extend in the first direction from below the first emitter electrode to the spaced region.

Supplementary Note 8
The semiconductor device according to supplementary note 7, in which the plurality of the trench portions include a third gate trench portion, and
the third gate trench portion includes:
   a third extending portion extending in the first direction from below the second emitter electrode to the spaced region, and
   a third connection portion provided in the spaced region and connecting the third extending portion to the first active gate runner.

Supplementary Note 9
The semiconductor device according to supplementary note 8, in which the plurality of the trench portions include a fourth gate trench portion, and
the fourth gate trench portion includes:
   a fourth extending portion extending in the first direction from below the second emitter electrode to the spaced region, and
   a fourth connection portion provided in the spaced region and connecting the fourth extending portion to the second active gate runner.

Supplementary Note 10
The semiconductor device according to supplementary note 7, including a bridge electrode portion provided in the spaced region and connecting the first emitter electrode and the second emitter electrode.

Supplementary Note 11
The semiconductor device according to any one of supplementary notes 1 to 10, in which the plurality of the trench portions have the fifth gate trench portion disposed farther away from the first active gate runner in the second direction than the first gate trench portion,
the fifth gate trench portion includes:
   a fifth extending portion extending in the first direction to the spaced region, and
   a fifth connection portion provided in the spaced region and connecting the fifth extending portion to the first active gate runner, and
the fifth extending portion extends farther inward in the spaced region in the first direction than the first extending portion.

Supplementary Note 12
The semiconductor device according to any one of supplementary notes 1 to 10, in which an interval a in the second direction of the plurality of the trench portions extending in the first direction to the spaced region and an interval b in the first direction of the plurality of the trench portions in the spaced region satisfy a following relationship:
   0.01 < b/a < 1.

Supplementary Note 13
The semiconductor device according to any one of supplementary notes 1 to 10, in which the plurality of the trench portions have a sixth gate trench portion connected to the first connection portion.

Supplementary Note 14
The semiconductor device according to supplementary note 13, in which:
   an interval a in the second direction of the plurality of the trench portions extending in the first direction to the spaced region,
   an interval b in the first direction of the plurality of the trench portions in the spaced region,
   a length c of the spaced region in the second direction,
   a length d of the first active gate runner in the first direction, and
   a number n of the sixth gate trench portions connected to one first connection portion satisfies a following relationship:
      2 × (c/a) × (n+1) ≥ d/b.

Supplementary Note 15
The semiconductor device according to any one of supplementary notes 1 to 10, in which the first active gate runner and the second active gate runner are formed of metal.

Supplementary Note 16
The semiconductor device according to supplementary note 15, in which a polysilicon gate runner is not provided between the first active gate runner and the second active gate runner and the upper surface of the semiconductor substrate.

Supplementary Note 17
The semiconductor device according to supplementary note 16, in which the first gate trench portion has a gate conductive portion of polysilicon, and
an upper end of the gate conductive portion is in contact with the first active gate runner.

Supplementary Note 18
The semiconductor device according to supplementary note 15, in which a gate runner of polysilicon connecting the first active gate runner and the second active gate runner is not provided in the spaced region.

Supplementary Note 19
The semiconductor device according to any one of supplementary notes 1 to 10, in which the plurality of trench portions have a seventh gate trench portion facing the first active gate runner in the first direction, and
the seventh gate trench portion extends in the first direction to below the first active gate runner and is connected to the first active gate runner.

Supplementary Note 20
The semiconductor device according to supplementary note 11, in which the plurality of trench portions have a first dummy trench portion provided between the first gate trench portion and the fifth gate trench portion, and
the first dummy trench portion extends in the first direction to the spaced region.

Supplementary Note 21
The semiconductor device according to any one of supplementary notes 1 to 10, in which the semiconductor substrate has:
   a drift region of a first conductivity type, and
   an emitter region of the first conductivity type provided on the upper surface of the semiconductor substrate and having a higher concentration than the drift region,
   and
   the emitter region is also provided in the spaced region.

Supplementary Note 22
The semiconductor device according to supplementary note 2 or 3, in which in the spaced region, transistor portions are provided in regions close to the first end side and the second end side, and
in the spaced region, a diode portion is provided between the transistor portions in the second direction.

Supplementary Note 23
The semiconductor device according to supplementary note 22, including a first emitter electrode and a second emitter electrode provided above the upper surface of the semiconductor substrate and arranged with the first active gate runner, the second active gate runner, and the spaced region interposed therebetween in the first direction, and
in the diode portion, the plurality of trench portions has a second dummy trench portion provided from below the first emitter electrode to below the second emitter electrode.

Supplementary Note 24
The semiconductor device according to any one of supplementary notes 1 to 6, including:
   an emitter electrode provided above the upper surface of the semiconductor substrate,
   a temperature sense portion at least partly provided in the spaced region, and
   a third active gate runner provided between the temperature sense portion and the emitter electrode,
   in which
   the plurality of trench portions has an eighth gate trench portion connected to the third active gate runner.

Supplementary Note 25
The according to supplementary note 1, in which the plurality of trench portions have a plurality of first gate trench portions including the first gate trench portions, and
the semiconductor device includes a first trench connection portion connecting the plurality of first connection portions to each other.

Supplementary Note 26
The semiconductor device according to supplementary note 6, in which the plurality of trench portions have a plurality of second gate trench portions including the second gate trench portion, and
the semiconductor device includes a second trench connection portion connecting the plurality of second connection portions to each other.

Supplementary Note 27
The semiconductor device according to supplementary note 8, in which the plurality of trench portions have a plurality of third gate trench portions including the third gate trench portion, and
the semiconductor device includes a third trench connection portion connecting the plurality of third connection portions to each other.

Supplementary Note 28
The semiconductor device according to supplementary note 8, including a fourth trench connection portion connecting the first connection portion and the third connection portion to each other.

What is claimed is:

1. A semiconductor device comprising:
a semiconductor substrate having an upper surface and a lower surface;
a plurality of trench portions provided from the upper surface of the semiconductor substrate toward an inside and extending in a first direction on the upper surface;
a first active gate runner extending in a second direction intersecting the first direction above the upper surface of the semiconductor substrate; and
a second active gate runner extending in the second direction and provided apart from the first active gate runner in the second direction, wherein
a spaced region is provided between the first active gate runner and the second active gate runner along the second direction,
the plurality of trench portions include a first gate trench portion, and
the first gate trench portion includes:
a first extending portion extending in the first direction to the spaced region, and
a first connection portion provided in the spaced region and connecting the first extending portion to the first active gate runner.

2. The semiconductor device according to claim 1, wherein
in a top view,
the first active gate runner has a first end side,
the second active gate runner has a second end side facing the first end side in the second direction, and
the first connection portion intersects the first end side.

3. The semiconductor device according to claim 2, wherein
the first connection portion extends to a portion overlapping the first active gate runner.

4. The semiconductor device according to claim 1, wherein
the first connection portion has a first straight portion extending in the second direction.

5. The semiconductor device according to claim 4, wherein
the first connection portion has a first curved portion connecting the first straight portion and the first extending portion.

6. The semiconductor device according to claim 1, wherein
the plurality of trench portions include a second gate trench portion, and
the second gate trench portion has:
a second extending portion extending in the first direction to the spaced region, and
a second connection portion provided in the spaced region and connecting the second extending portion to the second active gate runner.

7. The semiconductor device according to claim 6, comprising:
a first emitter electrode provided above the upper surface of the semiconductor substrate; and
a second emitter electrode disposed to face the first emitter electrode, sandwiching the first active gate runner, the second active gate runner, and the spaced region in the first direction, wherein
the first gate trench portion and the second gate trench portion extend in the first direction from below the first emitter electrode to the spaced region.

8. The semiconductor device according to claim 7, wherein
the spaced region is provided with a bridge electrode portion connecting the first emitter electrode and the second emitter electrode.

9. The semiconductor device according to claim 1, wherein
the plurality of trench portions have a fifth gate trench portion disposed farther from the first active gate runner in the second direction than the first gate trench portion,
the fifth gate trench portion has:
a fifth extending portion extending in the first direction to the spaced region, and
a fifth connection portion provided in the spaced region and connecting the fifth extending portion to the first active gate runner, and
the fifth extending portion extends farther inward in the spaced region in the first direction than the first extending portion.

10. The semiconductor device according to claim 1, wherein
an interval a in the second direction of the plurality of trench portions extending in the first direction to the spaced region and an interval b in the first direction of the plurality of trench portions in the spaced region satisfy a following relationship:
100.01 < b/a < 1.

11. The semiconductor device according to claim 1, wherein
the plurality of trench portions have a sixth gate trench portion connected to the first connection portion.

12. The semiconductor device according to claim 11, wherein
an interval a in the second direction of the plurality of trench portions extending in the first direction to the spaced region,
an interval b in the first direction of the plurality of trench portions in the spaced region,
a length c of the spaced region in the second direction,
a length d of the first active gate runner in the first direction, and
a number n of the sixth gate trench portions connected to one of the first connection portions, satisfy a following relationship:
22 × (c/a) × (n+1) ≥ d/b.

13. The semiconductor device according to claim 1, wherein
the first active gate runner and the second active gate runner are formed of metal.

14. The semiconductor device according to claim 1, wherein
the plurality of trench portions have a seventh gate trench portion facing the first active gate runner in the first direction, and
the seventh gate trench portion extends in the first direction to below the first active gate runner and is connected to the first active gate runner.

15. The semiconductor device according to claim 9, wherein
the plurality of trench portions have a first dummy trench portion provided between the first gate trench portion and the fifth gate trench portion, and
the first dummy trench portion extends in the first direction to the spaced region.

16. The semiconductor device according to claim 1, wherein
the semiconductor substrate has:
a drift region of a first conductivity type, and
an emitter region of the first conductivity type provided on the upper surface of the semiconductor substrate and having a higher concentration than the drift region, and
the emitter region is also provided in the spaced region.

17. The semiconductor device according to claim 2, wherein
in the spaced region, transistor portions are provided in regions close to the first end side and the second end side, and
a diode portion is provided between the transistor portions in the second direction in the spaced region.

18. The semiconductor device according to claim 17 comprising:
a first emitter electrode and a second emitter electrode provided above the upper surface of the semiconductor substrate and disposed to sandwich the first active gate runner, the second active gate runner, and the spaced region in the first direction, wherein
in the diode portion, the plurality of trench portions have a second dummy trench portion provided from below the first emitter electrode to below the second emitter electrode.

19. The semiconductor device according to claim 1, comprising:
an emitter electrode provided above the upper surface of the semiconductor substrate;
a temperature sense portion at least partly provided in the spaced region; and
a third active gate runner provided between the temperature sense portion and the emitter electrode, wherein
the plurality of trench portions have an eighth gate trench portion connected to the third active gate runner.

20. The semiconductor device according to claim 1, wherein
the plurality of trench portions have a plurality of first gate trench portions including the first gate trench portion, and
the semiconductor device has a first trench connection portion connecting the plurality of first connection portions to each other.
